(19) United States
(12) Patent Application Publication
(10) Pub. No.: US 2024/0346217 A1
(43) Pub. Date: Oct. 17, 2024

(54) SEMICONDUCTOR STRUCTURE AND METHOD FOR CORE-ONLY DESIGN

(71) Applicant: Taiwan Semiconductor Manufacturing Company, Ltd., Hsinchu (TW)

(72) Inventors: Jaw-Juinn Horng, Hsinchu City (TW); Szu-Chin Tsao, Hsinchu City (TW)

(21) Appl. No.: 18/299,427

(22) Filed: Apr. 12, 2023

(51) Int. Cl. G06F 30/33; G06F 30/327

(52) U.S. Cl. CPC G06F 30/33; G06F 30/327

(57) ABSTRACT

An integrated circuit includes a core domain having at least one core domain design rule limitation of a smaller device and a lower operating voltage, an input/output domain having at least one input/output domain design rule limitation of a larger device than the smaller device of the core domain and a higher operating voltage than the lower operating voltage of the core domain, and a mapping cell that includes two or more electrical devices that each meet the at least one core domain design rule limitation. The mapping cell is configured to be an input/output device and operate in the input/output domain at the higher operating voltage of the input/output domain.

### CROSS-REFERENCED

This application claims priority from U.S. Provisional Application No. 63/476,117, filed on Dec. 19, 2022, which is hereby fully incorporated by reference.

### BACKGROUND

Often, an integrated circuit (IC) includes different power domains, such as a core power domain in a core domain and an input/output (IO) power domain in an IO domain. The core domain includes circuits for performing functions of the IC, and the IO domain includes circuits that operate as interfaces between the circuits of the core domain and components external to the IC. Electrical devices in the core domain are smaller, occupying less die space, and operated at a lower voltage level, such as 0.75 volts, to enhance overall power consumption and operating speed. Electrical devices in the IO domain are larger, occupying a larger die space, and operated at a higher voltage level, such as 1.2 volts. Typically, the circuits in the IO domain include only the larger electrical devices of the IO domain with consideration for a safe-operating-area (SOA). However, with the continuous shrinking of devices at newer process nodes, electrical devices that operate at the higher voltage levels of the IO domain may not be obtainable with the smaller and thinner dimensions of the newer process nodes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating an electrical device for the IO domain of an integrated circuit, in accordance with some embodiments.

FIG. 2 is a diagram schematically illustrating a mapping cell, referred to as mapping cell.1, that includes two transistors, in accordance with some embodiments.

FIG. 3 is a diagram schematically illustrating a pair of mapping cells, in accordance with some embodiments.

FIG. 4 is a diagram schematically illustrating a simplified pair of mapping cells that can be derived from the pair of mapping cells of FIG. 3, in accordance with some embodiments.

FIG. 5 is a diagram schematically illustrating a mapping cell that includes three transistors, in accordance with some embodiments.

FIG. 6 is a diagram schematically illustrating a pair of mapping cells, in accordance with some embodiments.

FIG. 7 is a diagram schematically illustrating a simplified pair of mapping cells that can be derived from the pair of mapping cells of FIG. 6, in accordance with some embodiments.

FIG. 8 is a diagram schematically illustrating transformation and simplification of a stacked-gate IO circuit for analog-like transformation mapping, in accordance with some embodiments.

FIG. 9 is a diagram schematically illustrating transformation and simplification of a multi-gate IO circuit for analog-like transformation mapping, in accordance with some embodiments.

FIG. 10 is a diagram schematically illustrating a mapping cell configured to be used in rail-to-rail and digital-like applications, in accordance with some embodiments.

FIG. 11 is a diagram schematically illustrating a pair of mapping cells, in accordance with some embodiments.

FIG. 12 is a diagram schematically illustrating a simplified pair of mapping cells that can be derived from the pair of mapping cells of FIG. 11, in accordance with some embodiments.

FIG. 13 is a diagram schematically illustrating a mapping cell that includes four transistors and is configured to be used in rail-to-rail and digital-like applications, in accordance with some embodiments.

FIG. 14 is a diagram schematically illustrating a pair of mapping cells, in accordance with some embodiments.

FIG. 15 is a diagram schematically illustrating a simplified pair of mapping cells that can be derived from the pair of mapping cells of FIG. 14, in accordance with some embodiments.

FIG. 16 is a diagram schematically illustrating transformation and simplification of a digital IO circuit for rail-to-rail and digital-like transformation mapping, in accordance with some embodiments.

FIG. 17 is a diagram schematically illustrating an NMOS electrical device for the IO domain and NMOS mapping cells for the analog-like applications and the rail-to-rail and digital-like applications, in accordance with some embodiments.

FIG. 18 is a diagram schematically illustrating a PMOS electrical device for the IO domain and PMOS mapping cells for the analog-like applications and the rail-to-rail and digital-like applications, in accordance with some embodiments.

FIG. 19 is a diagram schematically illustrating an NMOS mapping cell that includes two cascode protection transistors, in accordance with some embodiments.

FIG. 20 is a diagram schematically illustrating an NMOS mapping cell that includes n cascode protection transistors, in accordance with some embodiments.

FIG. 21 is a diagram schematically illustrating a PMOS mapping cell that includes a transistor and two cascode protection transistors, in accordance with some embodiments.

FIG. 22 is a diagram schematically illustrating a PMOS mapping cell that includes a transistor and n cascode protection transistors, in accordance with some embodiments.

FIG. 23 is a diagram schematically illustrating an operational transconductance amplifier (OTA), in accordance with some embodiments.

FIG. 24 is a diagram schematically illustrating an inverter that includes mapping cells, in accordance with some embodiments.

FIG. 25 is a diagram schematically illustrating a NAND gate that includes mapping cells, in accordance with some embodiments.

FIG. 26 is a diagram schematically illustrating a Schmitt trigger that includes mapping cells, in accordance with some embodiments.

FIG. 27 is a diagram schematically illustrating a semiconductor structure of the electrical device of FIG. 1, in accordance with some embodiments.

FIG. 28 is a diagram schematically illustrating a semiconductor structure of the mapping cell of FIG. 2, in accordance with some embodiments.

FIG. 29 is a diagram schematically illustrating a semiconductor structure of the mapping cell of FIG. 2, which includes a dummy insertion structure (MDM), in accordance with some embodiments.

FIG. 30 is a diagram schematically illustrating a semiconductor structure of the mapping cell of FIG. 5, in accordance with some embodiments.

FIG. 31 is a diagram schematically illustrating a semiconductor structure of the mapping cell of FIG. 5, which includes an MDM, in accordance with some embodiments.

FIG. 32 is a diagram schematically illustrating a parallel combination of mapping cells, in accordance with some embodiments.

FIG. 33 is a diagram schematically illustrating a semiconductor structure of the parallel combination of mapping cells of FIG. 32, in accordance with some embodiments.

FIG. 34 is a diagram schematically illustrating a series combination of mapping cells, in accordance with some embodiments.

FIG. 35 is a diagram schematically illustrating a semiconductor structure of the series combination of mapping cells of FIG. 34, in accordance with some embodiments.

FIG. 36 is a diagram schematically illustrating a cascode transistor manufactured by back-end-of-line (BEOL) processes, in accordance with some embodiments.

FIG. 37 is a diagram schematically illustrating a method of transforming IO domain circuits into core domain mapping cells, in accordance with some embodiments.

FIG. 38 is a diagram schematically illustrating a mapping method, in accordance with some embodiments.

FIG. 39 is a block diagram schematically illustrating an example of a computer system configured to provide the semiconductor devices and methods of the current disclosure, in accordance with some embodiments.

FIG. 40 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Disclosed embodiments provide structures and methods for replacing electrical devices that meet design rule limitations of an IO domain with two or more electrical devices that meet design rule limitations of a core domain. This can provide a core device only design and design flow that maintains comparable performance to electrical devices that meet the design rule limitations of the IO domain and a SOA for the higher voltages of the IO domain, which avoids overstressing the core devices.

The core domain electrical devices are smaller, occupying less die space, and operated at lower voltage levels, such as 0.75 volts, to enhance overall power consumption and operating speed. The design rule limitations of the core domain include the smaller electrical devices and operating at lower voltage levels. The IO domain electrical devices are larger, occupying a larger die space, and operated at higher voltage levels, such as 1.2 volts. The design rule limitations of the IO domain include larger electrical devices and operating at higher voltage levels.

In some embodiments, a metal-oxide semiconductor field-effect transistor (MOSFET) that meets the design rule limitations of the IO domain is replaced with a mapping cell that meets the design rule limitations of the core domain. The mapping cell includes two or more core devices and is operated in the IO domain at the higher voltage levels of the IO domain. Also, in some embodiments, the mapping cell can include one or more n-channel MOSFETS and/or one or more p-channel MOSFETS.

Advantages of the disclosed embodiments include mapping cells that work as unit cells in the design and layout of an IC to achieve quick and easy replacement, mapping cells composed of one or more cascode protection devices that allow connections to higher voltages, and mapping cells that have comparable power, performance, and area (PPA) to electrical devices that meet the design rule limitations of the IO domain. Also, this design flow provides for analog-based design like band-gap circuits and for digital-like analog design as in mixed-signal circuits.

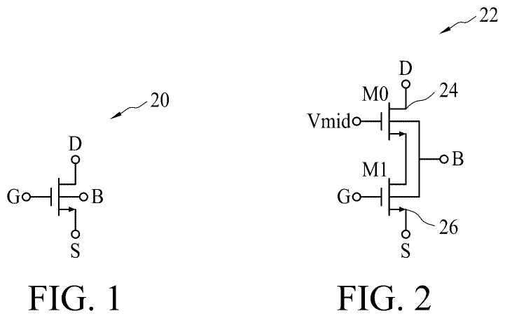

FIG. 1 is a diagram schematically illustrating an electrical device 20 for the IO domain of an integrated circuit, in accordance with some embodiments. The electrical device 20 is configured to meet the design rule limitations of the IO domain, where the design rule limitations of the IO domain include larger electrical devices and operating at the higher voltage level of the IO domain. The electrical device 20 is larger, occupying a larger die space on the integrated circuit, than core domain electrical devices and the electrical device 20 can be operated at the higher voltage level of the IO domain without breaking down or damaging the electrical device 20. The electrical device 20 is an n-channel MOSFET that includes a drain node D, a gate node G, a source node S, and a body node B. In other embodiments, the electrical device 20 can be a p-channel MOSFET.

FIG. 2 is a diagram schematically illustrating a mapping cell 22, referred to as mapping cell.1, that includes transistors M0 24 and M1 26, in accordance with some embodiments. Transistor M0 24 is an n-channel MOSFET and transistor M1 26 is an n-channel MOSFET. Each of the transistors M0 24 and M1 26 meets the design rule limitations of the core domain. where the design rule limitations of the core domain include smaller electrical devices and operating at the lower voltage level of the core domain. In some embodiments, the mapping cell 22 is configured to replace the electrical device 20 in the IO domain of the integrated circuit. In other embodiments, at least one of the transistors M0 24 and M1 26 is a p-channel MOSFET.

The mapping cell 22 includes a drain node D, a gate node G, a source node S, and a body node B. In addition, the mapping cell 22 includes a gate node Vmid for biasing the transistor M0 24. The transistor M0 24 includes the drain node D, the gate node Vmid, and a source node that is connected in series to a drain node of the transistor M1 26. The transistor M1 26 includes the gate node G and the source node S. Also, each of the transistors M0 24 and M1 26 includes the body node B. In some embodiments, the drain node D, the gate node G, the source node S, and the body node B are like the nodes of the electrical device 20 of FIG. 1.

In mapping from the electrical device 20 to the mapping cell 22, the ratio of the number of transistors M0 24 to the electrical device 20 can be set as 1, 2, . . . n based on the PPA requirements of the IO electrical device. Also, in mapping from the IO electrical device 20 to the mapping cell 22, the ratio of the number of transistors M1 26 to the electrical device 20 can be set as 1, 2, . . . n based on the PPA requirements of the IO electrical device.

In analog operation, the gate-to-source voltage Vgs of each of the transistors M0 24 and M1 26 is set to core operating levels of an analog circuit in the core domain. Transistor M0 24 is a cascode transistor that is connected in series to the drain of transistor M1 26. This cascode transistor M0 24 is biased to prevent transistor M1 26 from being broken down or damaged when the higher voltage of the IO domain is applied to the drain node D of the mapping cell 22.

Also, in analog operation, the voltage applied to the gate node G of mapping cell 22 is an analog signal, where the following conditions are satisfied. First, the maximum drain-to source voltage Vds of transistor M1 26 is less than the voltage Vmid at the gate node Vmid, and second the gate-to-source voltage Vgs of transistor M1 26 is less than or equal to Vmid. Thus, the mapping cell 22 can replace the electrical device 20 in the IO domain of the integrated circuit without breaking down or damaging the transistors M0 24 and M1 26.

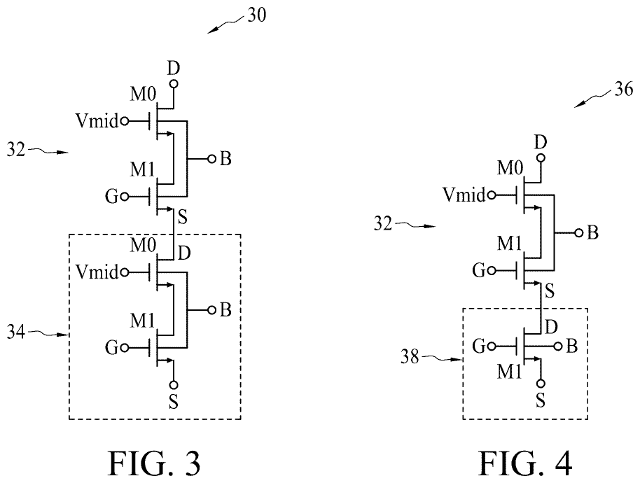

FIGS. 3 and 4 are diagrams schematically illustrating simplification of mapping cells for analog-like transformation mapping, in accordance with some embodiments. Two mapping cells that are each like mapping cell 22, i.e., mapping cell.1, are connected in series to one another and the circuit is simplified by removing one of the cascode transistors M0.

FIG. 3 is a diagram schematically illustrating a pair of mapping cells 30, in accordance with some embodiments. The pair of mapping cells 30 includes a first mapping cell 32 and a second mapping cell 34. Each of the mapping cells 32 and 34 is like mapping cell 22 of FIG. 2 and includes a drain node D, a gate node Vmid, a gate node G, a source node S, and a body node B. The source node S of mapping cell 32 is connected in series to the drain node D of the mapping cell 34.

FIG. 4 is a diagram schematically illustrating a simplified pair of mapping cells 36 that can be derived from the pair of mapping cells 30, in accordance with some embodiments. The mapping cell 32 remains unchanged and the mapping cell 34 is reduced by removing the cascode transistor M0. The remaining transistor M1 of the mapping cell 34, referred to as mapping cell. 1b 38, includes a drain node D, a gate node G, a source node S, and a body node B. The source node S of the mapping cell 32 is connected in series to the drain node D of the mapping cell.1b 38.

In operation, the gate nodes G of the simplified pair of mapping cells 36 are biased by one or more voltages of the core domain, and the drain node D of the mapping cell 32 receives the voltage of the IO domain. Thus, the upper mapping cell 32 remains in the two transistor M0 and M1 configuration, but the lower mapping cell 34 is simplified to just one transistor M1, i.e., to mapping cell.1b 38. In some embodiments, this simplification technique can be extended to stacked-gate transformations and/or to multi-gate transformations.

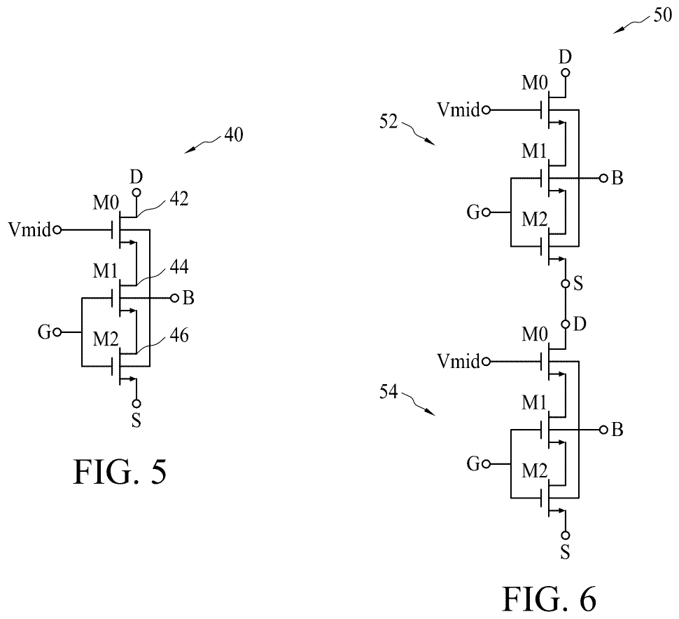

FIG. 5 is a diagram schematically illustrating a mapping cell 40 that includes three transistors M0 42, M1 44, and M2 46, in accordance with some embodiments. The mapping cell 40, referred to as a mapping cell.2, includes a cascode transistor M0 42 and two series connected core transistors M1 44 and M2 46. Each of the transistors M0 42, M1 44, and M2 46 is an n-channel MOSFET. In some embodiments, the mapping cell 40 is configured to replace the electrical device 20 in the IO domain of the integrated circuit. In other embodiments, at least one of the transistors M0 42, M1 44, and M2 46 is a p-channel MOSFET.

The mapping cell 40 includes a drain node D, a gate node G, a source node S, and a body node B. In addition, the mapping cell 40 includes a gate node Vmid for biasing the cascode transistor M0 42. Each of the transistors M0 42, M1 44, and M2 46 meets the design rule limitations of the core domain. The transistor M0 42 includes the drain node D, the gate node Vmid, and a source node that is connected in series to a drain node of the transistor M1 44. The transistor M1 44 includes the gate node G and a source node that is connected in series to a drain node of the transistor M2 46, and the transistor M2 46 includes the gate node G and the source node S. Also, each of the transistors M0 42, M1 44, and M2 46 includes the body node B. In some embodiments, the drain node D, the gate node G, the source node S, and the body node B are like the nodes of the electrical device 20 of FIG. 1.

In mapping from the electrical device 20 to the mapping cell 40, the ratio of the number of transistors M0 42 to the electrical device 20 can be set as 1, 2, . . . n based on the PPA requirements of the IO electrical device. Also, in mapping from the IO electrical device 20 to the mapping cell 40, each of the ratio of the number of transistors M1 44 to the electrical device 20 can be set as 1, 2, . . . n and the ratio of the number of transistors M2 46 to the electrical device 20 can be set as 1, 2, . . . n based on the PPA requirements of the IO electrical device.

In analog operation, the gate-to-source voltage Vgs of each of the transistors M0 42, M1 44, and M2 46 is set to a core operating level of an analog circuit in the core domain. Transistor M0 42 is the cascode transistor connected in series to the two core transistors M1 44 and M2 46. The cascode transistor M0 42 is biased to protect transistors M1 44 and M2 46 from being broken down or damaged when the higher voltage of the IO domain is applied to the drain node D of the mapping cell 40. Also, the voltage applied to the gate node G of mapping cell 40 is an analog signal. Thus, the mapping cell 40 can replace the electrical device 20 in the IO domain of the integrated circuit without breaking down or damaging the transistors M0 42, M1 44, and M2 46.

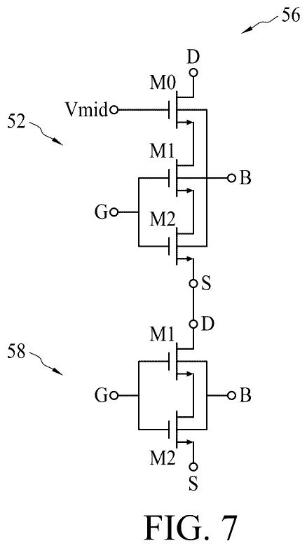

FIGS. 6 and 7 are diagrams schematically illustrating simplification of mapping cells for analog-like transformation mapping, in accordance with some embodiments. Two mapping cells that are each like mapping cell 40, i.e., mapping cell.2, are connected in series to one another and the circuit is simplified by removing one of the cascode transistors M0.

FIG. 6 is a diagram schematically illustrating a pair of mapping cells 50, in accordance with some embodiments. The pair of mapping cells 50 includes a first mapping cell 52 and a second mapping cell 54. Each of the mapping cells 52 and 54 is like mapping cell 40 of FIG. 5 and includes a drain node D, a gate node Vmid, a gate node G, a source node S, and a body node B. The source node S of mapping cell 52 is connected in series to the drain node D of the mapping cell 54.

FIG. 7 is a diagram schematically illustrating a simplified pair of mapping cells 56 that can be derived from the pair of mapping cells 50, in accordance with some embodiments. The mapping cell 52 remains unchanged and the mapping cell 54 is reduced by removing the cascode transistor M0. The remaining transistors M1 and M2 of the mapping cell 54, referred to as mapping cell.2b 58, includes a drain node D, a gate node G, a source node S, and a body node B. The source node S of the mapping cell 52 is connected in series to the drain node D of the mapping cell.2b 58.

In operation, the gate nodes G of the simplified pair of mapping cells 56 are biased by one or more voltages of the core domain, and the drain node D of the mapping cell 52 receives the voltage of the IO domain. Thus, the upper mapping cell 52 remains in the three transistor M0, M1, and M2 configuration, but the lower mapping cell 54 is simplified to just two transistors M1 and M2, i.e., to mapping cell.2b 58. In some embodiments, this simplification technique can be extended to stacked-gate transformations and/or to multi-gate transformations.

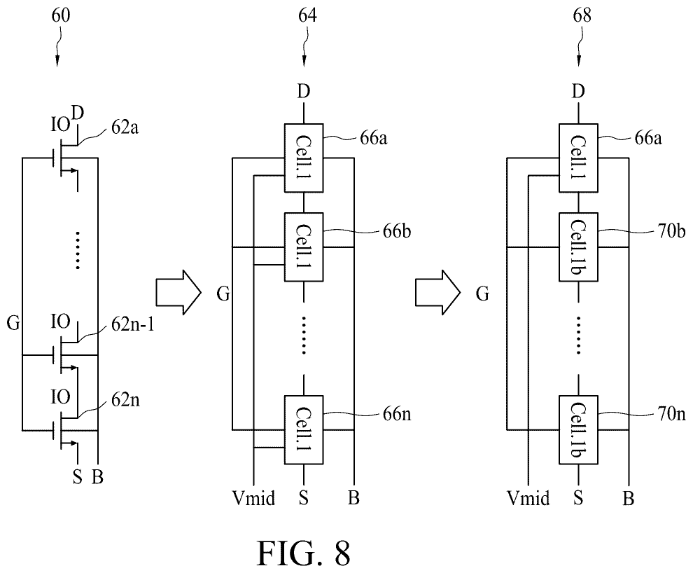

FIG. 8 is a diagram schematically illustrating transformation and simplification of a stacked-gate IO circuit 60 for analog-like transformation mapping, in accordance with some embodiments. The stacked-gate IO circuit 60 is configured for operating in the IO domain and includes multiple electrical devices 62a-62n connected in series with the source of one of the electrical devices 62a-62n connected to the drain of the next one of the electrical devices 62a-62n. Each of the electrical devices 62a-62n is configured to meet the design rule limitations of the IO domain, which includes operating at the higher voltage level of the IO domain. The electrical devices 62a-62n are larger, occupying more die space, than core domain electrical devices and the electrical devices 62a-62n can be operated at the higher voltage level of the IO domain without breaking down or damaging the electrical devices 62a-62n. Also, each of the electrical devices 62a-62n is an n-channel MOSFET. In other embodiments, at least one and up to all the electrical devices 62a-62n are a p-channel MOSFET.

The stacked-gate IO circuit 60 includes a drain node D, a gate node G, a source node S. and a body node B. The electrical device 62a includes the drain node D and the electrical device 62n includes the source node S. Each of the electrical devices 62a-62n includes and is attached to the gate node G and the body node B.

In a first transformation circuit 64, each of the electrical devices 62a-62n is replaced with a mapping cell. 1 that is the mapping cell 22 of FIG. 2. The mapping cells 66a-66n are connected in series, such as in mapping cell 30 of FIG. 3, with the source node S of one of the mapping cells 66a-66n connected to the drain node D of the next one of the mapping cells 66a-66n. The mapping cell 66a includes the drain node D of the first transformation circuit 64 and the mapping cell 66n includes the source node S of the first transformation circuit 64. Each of the mapping cells 66a-66n includes and is attached to the gate node G and the body node B of the first transformation circuit 64. In addition, each of the mapping cells 66a-66n includes and is attached to a gate node Vmid of the first transformation circuit 64.

In a second transformation circuit 68, the first mapping cell 66a remains a mapping cell. 1, and the rest of the mapping cells 66b-66n are reduced to mapping cells 70b-70n that are each a mapping cell.1b, i.e., the mapping cell. 1b 38 (shown in FIG. 4). The mapping cells 66a and 70b are connected in series, such as in the mapping cell 36 of FIG. 4. Also, the mapping cells 70b-70n are connected in series with the source of one of the mapping cells 70b-70n connected to the drain of the next one of the mapping cells 70b-70n. The mapping cell 66a includes the drain node D and the gate node Vmid, and the mapping cell 70n includes the source node S. Each of the mapping cells 66a and 70b-70n includes and is attached to the gate node G and the body node B of the second transformation circuit 68.

In other embodiments, at least one and up to all the mapping cells 66a-66n is a mapping cell.2, such as mapping cell 40 of FIG. 5. Also, in other embodiments, at least one and up to all the mapping cells 70b-70n is a mapping cell.2b, such as mapping cell 58 (shown in FIG. 7).

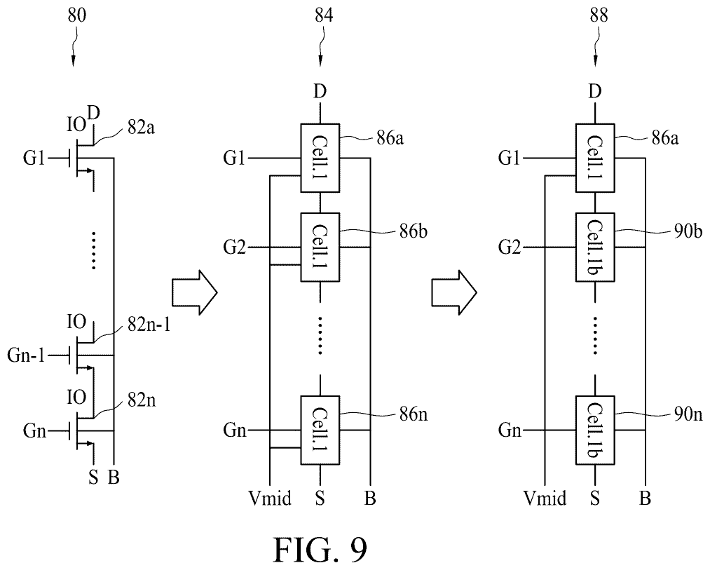

FIG. 9 is a diagram schematically illustrating transformation and simplification of a multi-gate IO circuit 80 for analog-like transformation mapping, in accordance with some embodiments. The multi-gate IO circuit 80 is configured for operating in the IO domain and includes multiple electrical devices 82a-82n connected in series with the source of one of the electrical devices 82a-82n connected to the drain of the next one of the electrical devices 82a-82n. Each of the electrical devices 82a-82n is configured to meet the design rule limitations of the IO domain, which includes operating at the higher voltage level of the IO domain. The electrical devices 82a-82n are larger, occupying more die space, than core domain electrical devices and the electrical devices 82a-82n can be operated at the higher voltage level of the IO domain without breaking down or damaging the electrical devices 82a-82n. Also, each of the electrical devices 82a-82n is an n-channel MOSFET. In other embodiments, at least one and up to all the electrical devices 82a-82n are a p-channel MOSFET.

The multi-gate IO circuit 80 includes a drain node D, gate nodes G1-Gn, a source node S, and a body node B. The electrical device 82a includes the gate node G1 and the drain node D, the electrical device 82n-1 includes the gate node Gn-1, and the electrical device 82n includes the gate node Gn and the source node S. Each of the electrical devices 82a-82n includes a corresponding one of the gate nodes G1-Gn and is attached to the body node B.

In a first transformation circuit 84, each of the electrical devices 82a-82n is replaced with a mapping cell. 1 that is the mapping cell 22 of FIG. 2. The mapping cells 86a-86n are connected in series, such as in mapping cell 30 of FIG. 3, with the source node S of one of the mapping cells 86a-86n connected to the drain node D of the next one of the mapping cells 86a-86n. The mapping cell 86a includes the gate node G1 and the drain node D of the first transformation circuit 84, the mapping cell 86b includes the gate node G2, and the mapping cell 86n includes the gate node Gn and the source node S of the first transformation circuit 84. Each of the mapping cells 86a-86n includes a corresponding gate node G1-Gn and is attached to the body node B of the first transformation circuit 84. In addition, each of the mapping cells 86a-86n is attached to a gate node Vmid of the first transformation circuit 84.

In a second transformation circuit 88, the first mapping cell 86a remains a mapping cell. 1, and the rest of the mapping cells 86b-86n are reduced to mapping cells 90b-90n that are each a mapping cell.1b, i.e., the mapping cell. 1b 38 (shown in FIG. 4). The mapping cells 86a and 90b are connected in series, such as in the mapping cell 36 of FIG. 4. Also, the mapping cells 90b-90n are connected in series with the source of one of the mapping cells 90b-90n connected to the drain of the next one of the mapping cells 90b-90n. The mapping cell 86a includes the gate nodes G1 and Vmid and the drain node D, the mapping cell 90b includes the gate node G2, and the mapping cell 90n includes the gate node Gn and the source node S. Each of the mapping cells 86a and 90b-90n includes a corresponding one of the gate nodes G1-Gn and is attached to the body node B of the second transformation circuit 88.

In other embodiments, at least one and up to all the mapping cells 86a-86n is a mapping cell.2, such as mapping cell 40 of FIG. 5. Also, in other embodiments, at least one and up to all the mapping cells 90b-90n is a mapping cell.2b, such as mapping cell 58 (shown in FIG. 7).

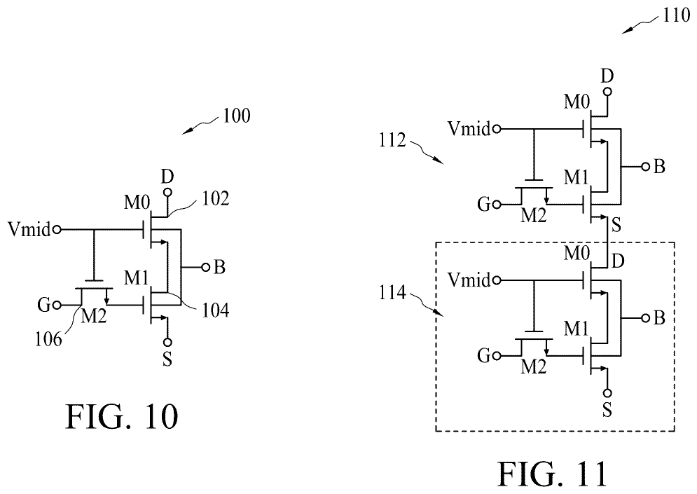

FIGS. 10-15 are diagrams schematically illustrating mapping cells to be used in rail-to-rail and digital-like applications, in accordance with some embodiments. In some embodiments, an integrated circuit includes digital logic circuits and/or analog circuits like Schmitt triggers that are operated in the IO domain. In these circuits, the voltage applied to the gate node G of an electrical device may be a digital signal that is switched between a reference voltage, such as 0 volts, and an IO domain voltage, such as 1.2 volts. Thus, mapping cells that include core electrical devices need to be able to tolerate the higher IO domain voltage, such as 1.2 volts, at the gate nodes G.

FIG. 10 is a diagram schematically illustrating a mapping cell 100 configured to be used in rail-to-rail and digital-like applications, in accordance with some embodiments. The mapping cell 100, referred to as mapping cell.3, includes transistors M0 102, M1 104, and M2 106. Each of the transistors M0 102, M1 104, and M2 106 meets the design rule limitations of the core domain. The mapping cell 100 includes a drain node D, a gate node Vmid for biasing the transistors M0 102 and M2 106, a gate node G, a source node S, and a body node B. In some embodiments, the drain node D, the gate node G, the source node S, and the body node B are like the nodes of the electrical device 20 of FIG. 1. In some embodiments, the mapping cell 100 is configured to replace the electrical device 20 of FIG. 1 in the IO domain of an integrated circuit.

The transistor M0 102 includes the drain node D, the gate node Vmid, and a source region connected in series to a drain region of transistor M1 104. The transistor M1 104 includes the source node S and a gate connected to a source region of transistor M2 106. The transistor M2 106 includes a gate connected to the gate node Vmid and the gate of transistor M0 102, and a drain region connected to the gate node G of the mapping cell 100 to receive a digital signal that is switched between a reference voltage, such as 0 volts, and an IO domain voltage, such as 1.2 volts. Each of the transistors M0 102 and M1 104 includes the body node B. Also, each of the transistors M0 102, M1 104, and M2 106 is an n-channel MOSFET. In other embodiments, at least one and up to all the transistors M0 102, M1 104, and M2 106 is a p-channel MOSFET.

In mapping from the electrical device 20 to the mapping cell 100, the ratio of the number of transistors M0 102 to the electrical device 20 can be set as 1, 2, . . . n based on the PPA requirements of the IO electrical device. Also, in mapping from the IO electrical device 20 to the mapping cell 100, each of the ratio of the number of transistors M1 104 to the electrical device 20 can be set as 1, 2, . . . n and the ratio of the number of transistors M2 106 to the electrical device 20 can be set as 1, 2, . . . n based on the PPA requirements of the IO electrical device.

In operation of mapping cell 100, if the gate node G is at a low voltage, such as 0 volts, with gate node Vmid set at 0.75 volts, then the transistor M2 106 is biased on and the gate of transistor M1 104 is at a low voltage, such as 0 volts, to bias off transistor M1 104. If the gate node G is at a high voltage, such as 1.2 volts, with the gate node Vmid set at 0.75 volts, the transistor M2 106 is biased off and the gate of transistor M1 104 is clamped by transistor M2 106 to a high voltage, such as 0.75 volts, to bias on transistor M1 104. The gate voltage of transistor M1 104 is determined by Vmid, such that the gate voltage of transistor M1 104 is approximate to Vmid but less than Vmid, i.e., the gate voltage of transistor M1 104<Vmid.

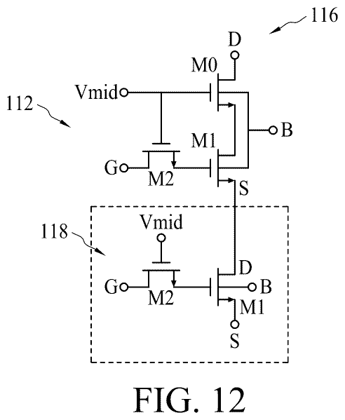

FIGS. 11 and 12 are diagrams schematically illustrating simplification of mapping cells for rail-to-rail and digital-like transformation mapping, in accordance with some embodiments. Two mapping cells that are each like mapping cell 100, i.e., mapping cell.3, are connected in series to one another and the circuit is simplified by removing one of the cascode transistors M0.

FIG. 11 is a diagram schematically illustrating a pair of mapping cells 110, in accordance with some embodiments. The pair of mapping cells 110 includes a first mapping cell 112 and a second mapping cell 114. Each of the mapping cells 112 and 114 is like mapping cell 100 of FIG. 10 and includes a drain node D, a gate node Vmid, a gate node G, a source node S, and a body node B. The source node S of mapping cell 112 is connected in series to the drain node D of the mapping cell 114.

FIG. 12 is a diagram schematically illustrating a simplified pair of mapping cells 116 that can be derived from the pair of mapping cells 110, in accordance with some embodiments. The mapping cell 112 remains unchanged and the mapping cell 114 is reduced by removing the cascode transistor M0. The remaining transistors M1 and M2 of the mapping cell 114, referred to as mapping cell.3b 118, include a drain node D, a gate node Vmid, a gate node G, a source node S, and a body node B. The transistor M1 includes the drain node D, the source node S, and the body node B, and the transistor M2 includes the gate node Vmid and the gate node G. The source node S of the mapping cell 112 is connected in series to the drain node D of the mapping cell.3b 118.

In operation, the gate nodes Vmid receive a bias voltage and the drain node D of the mapping cell 112 receives a voltage of the IO domain. Also, the gate nodes G of the simplified pair of mapping cells 116 receive one or more voltages of the IO domain, such as a digital signal that is switched between a reference voltage, such as 0 volts, and an IO domain voltage, such as 1.2 volts. Thus, the upper mapping cell 112 remains in the three transistor M0, M1, M2 configuration, but the lower mapping cell 114 is simplified to just two transistors M1 and M2, i.e., to mapping cell.3b 118. In some embodiments, this simplification technique can be extended to rail-to-rail and digital-like applications.

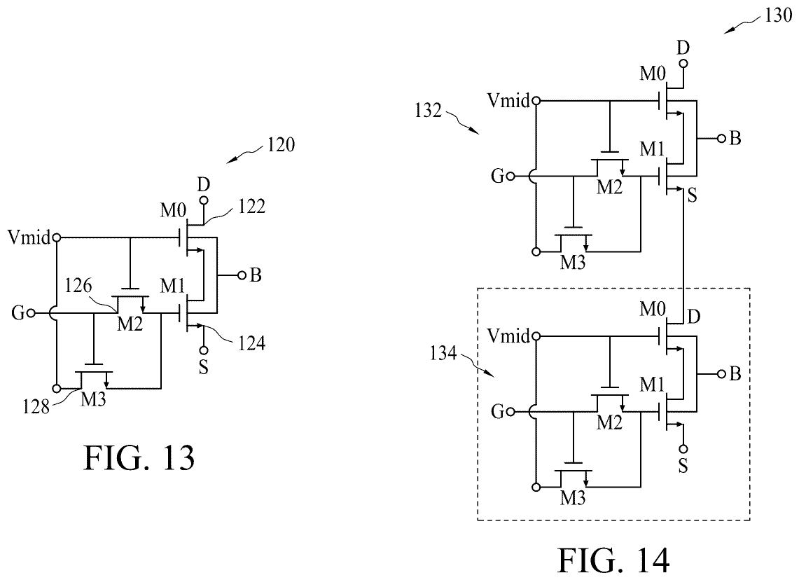

FIG. 13 is a diagram schematically illustrating a mapping cell 120 that includes four transistors M0 122, M1 124, M2 126, and M3 128 and is configured to be used in rail-to-rail and digital-like applications, in accordance with some embodiments. Each of the transistors M0 122, M1 124, M2 126, and M3 128 meets the design rule limitations of the core domain. The mapping cell 120, referred to as mapping cell.4, includes a drain node D, a gate node Vmid for biasing the transistors M0 122 and M2 126, a gate node G, a source node S, and a body node B. In some embodiments, the drain node D, the gate node G, the source node S, and the body node B are like the nodes of the electrical device 20 of FIG. 1. In some embodiments, the mapping cell 120 is configured to replace the electrical device 20 of FIG. 1 in the IO domain of an integrated circuit.

The transistor M0 122 includes the drain node D, the gate node Vmid, and a source region connected in series to a drain region of transistor M1 124. The transistor M1 124 includes the source node S and a gate connected to a source region of transistor M2 126 and to a source region of transistor M3 128. The transistor M2 126 includes a gate connected to the gate node Vmid and to a drain region of transistor M3 128. A drain region of transistor M2 126 is connected to the gate node G and to a gate of transistor M3 128 to receive a digital signal that is switched between a reference voltage, such as 0 volts, and an IO domain voltage, such as 1.2 volts. Each of the transistors M0 122 and M1 124 includes the body node B. Also, each of the transistors M0 122, M1 124, M2 126, and M3 128 is an n-channel MOSFET. In other embodiments, at least one and up to all the transistors M0 122, M1 124, M2 126, and M3 128 is a p-channel MOSFET.

In mapping from the electrical device 20 to the mapping cell 120, the ratio of the number of transistors M0 122 to the electrical device 20 can be set as 1, 2, . . . n based on the PPA requirements of the IO electrical device. Also, in mapping from the IO electrical device 20 to the mapping cell 120, each of the ratio of the number of transistors M1 124 to the electrical device 20 can be set as 1, 2, . . . n and the ratio of the number of transistors M2 126 to the electrical device 20 can be set as 1, 2, . . . n and the ratio of the number of transistors M3 128 to the electrical device 20 can be set as 1, 2, . . . n based on the PPA requirements of the IO electrical device.

In operation of mapping cell 120, if the gate node G is at a low voltage, such as 0 volts, with gate node Vmid set at 0.75 volts, then the transistor M2 126 is biased on and the gate of transistor M1 124 is at a low voltage, such as 0 volts, to bias off transistor M1 124. If the gate node G is at a high voltage, such as 1.2 volts, with the gate node Vmid set at 0.75 volts, the transistor M2 126 is biased off and the transistor M3 128 is biased on, such that the gate of transistor M1 124 is set to Vmid and the transistor M1 124 is biased on. The transistor M3 128 is connected to the gate of transistor M1 124 to enhance the gate-to-source voltage Vgs of transistor M1 124. The transistor M3 128 is added to ensure that the gate voltage of transistor M1 124 is equal to Vmid if the gate node G is at a high voltage. Accordingly, the mapping cell 120 can be used in a circuit with a high slew rate (SR) including a fast rise time and/or a fast fall time.

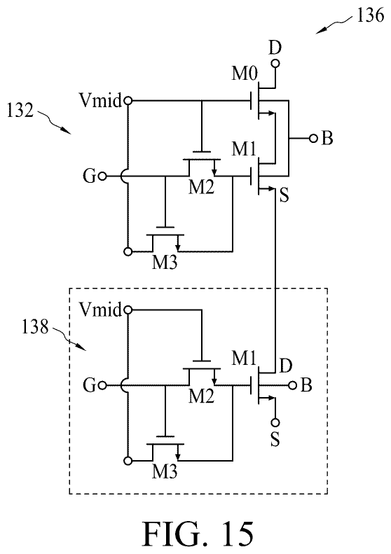

FIGS. 14 and 15 are diagrams schematically illustrating simplification of a pair of mapping cells 130 for rail-to-rail and digital-like transformation mapping, in accordance with some embodiments. Two mapping cells that are each like mapping cell 120, i.e., mapping cell.4, are connected in series to one another and the pair of mapping cells 130 is simplified by removing one of the cascode transistors M0.

FIG. 14 is a diagram schematically illustrating the pair of mapping cells 130, in accordance with some embodiments. The pair of mapping cells 130 includes a first mapping cell 132 and a second mapping cell 134. Each of the mapping cells 132 and 134 is like mapping cell 120 of FIG. 13 and includes a drain node D, a gate node Vmid, a gate node G, a source node S, and a body node B. The source node S of mapping cell 132 is connected in series to the drain node D of the mapping cell 134.

FIG. 15 is a diagram schematically illustrating a simplified pair of mapping cells 136 that can be derived from the pair of mapping cells 130, in accordance with some embodiments. The mapping cell 132 remains unchanged and the mapping cell 134 is reduced by removing the cascode transistor M0. The remaining transistors M1, M2, and M3 of the mapping cell 134, referred to as mapping cell.4b 138, include a drain node D, a gate node Vmid, a gate node G, a source node S. and a body node B. The transistor M1 includes the drain node D, the source node S, and the body node B, and the transistors M2 and M3 include the gate nodes Vmid and G. The source node S of the mapping cell 132 is connected in series to the drain node D of the mapping cell.4b 138.

In operation, the gate nodes Vmid receive a bias voltage and the drain node D of the mapping cell 132 receives a voltage of the IO domain. Also, the gate nodes G of the simplified pair of mapping cells 136 are biased by one or more voltages of the IO domain, such as a digital signal that is switched between a reference voltage, such as 0 volts, and an IO domain voltage, such as 1.2 volts. Thus, the upper mapping cell 132 remains in the three transistor M0, M1, M2 configuration, but the lower mapping cell 134 is simplified to just two transistors M1 and M2, i.e., to mapping cell.4b 138. In some embodiments, this simplification technique can be extended to rail-to-rail and digital-like applications. Also, in some embodiments, the mapping cells and mapping cell simplification techniques are extended to n-channel MOSFET mapping cells and p-channel MOSFET mapping cells.

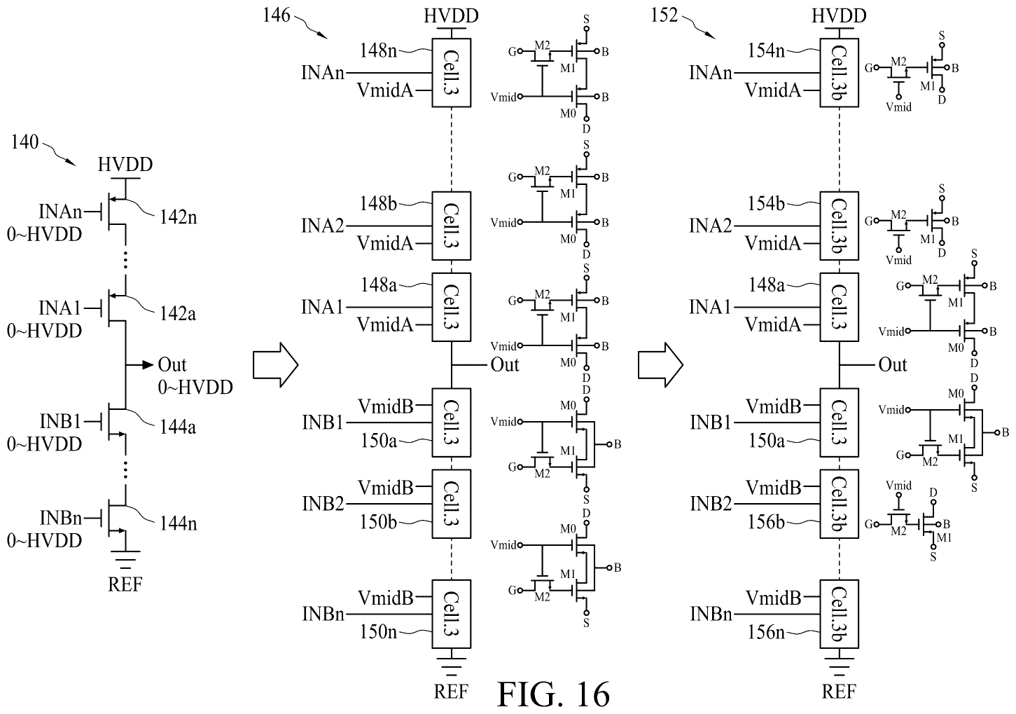

FIG. 16 is a diagram schematically illustrating transformation and simplification of a digital IO circuit 140 for rail-to-rail and digital-like transformation mapping, in accordance with some embodiments. The digital IO circuit 140 is configured to operate in the IO domain and includes p-channel MOSFETs 142a-142n and n-channel MOSFETs 144a-144n. The p-channel MOSFETs 142a-142n are connected in series with the drain of one of the p-channel MOSFETs 142a-142n connected to the source of the next one of the p-channel MOSFETs 142a-142n. Also, the n-channel MOSFETs 144a-144n are connected in series with the source of one of the n-channel MOSFETs 144a-144n connected to the drain of the next one of the n-channel MOSFETs 144a-144n. The drain of the p-channel MOSFET 142a is connected in series to the drain of the n-channel MOSFET 144a at an output node OUT.

Each of the p-channel MOSFETs 142a-142n and each of the n-channel MOSFETs 144a-144n is configured to meet the design rule limitations of the IO domain, which includes operating at the higher voltage level of the IO domain. The p-channel MOSFETs 142a-142n and the n-channel MOSFETs 144a-144n are larger, occupying more die space, than core domain electrical devices and the p-channel MOSFETs 142a-142n and the n-channel MOSFETs 144a-144n can be operated at the higher voltage level of the IO domain without breaking down or damaging the p-channel MOSFETs 142a-142n or the n-channel MOSFETs 144a-144n.

The digital IO circuit 140 includes a power node HVDD, input gate nodes INA1-INAn and INB1-INBn, and a reference node REF, such as ground. The p-channel MOSFET 142a includes the input gate node INA1 and is connected to the output node OUT, and the p-channel MOSFET 142n includes the input gate node INAn and the power node HVDD. Each of the p-channel MOSFETs 142a-142n includes a corresponding one of the input gate nodes INA1-INAn. The n-channel MOSFET 144a includes the input gate node INB1 and is connected to the output node OUT, and the n-channel MOSFET 144n includes the input gate INBn and the reference node REF. Each of the n-channel MOSFETs 144a-144n includes a corresponding one of the input gate nodes INB1-INBn.

The power node HVDD receives the higher voltage of the IO domain, such as 1.2 volts, and each of the input gate nodes INA1-INAn and INB1-INBn is configured to receive a digital signal from 0 volts to the high voltage of the IO domain HVDD, such as 1.2 volts.

In a first transformation circuit 146, each of the p-channel MOSFETs 142a-142n is replaced with a mapping cell.3 that is a p-channel version of the mapping cell 100 of FIG. 10. The mapping cells 148a-148n are connected in series with the drain node D of one of the mapping cells 148a-148n connected to the source node S of the next one of the mapping cells 148a-148n. The mapping cells 148a-148n include gate nodes G that are connected as input gate nodes INA1-INAn. The mapping cell 148a includes the input gate node INA1 and is connected to the output node OUT, and the mapping cell 148n includes the input gate node INAn and the power node HVDD. Also, each of the mapping cells 148a-148n includes a corresponding one of the input gate nodes INA1-INAn. In addition, each of the mapping cells 148a-148n is attached to a gate node VmidA of the first transformation circuit 146.

Also, in the first transformation circuit 146, each of the n-channel MOSFETs 144a-144n is replaced with a mapping cell.3 that is an n-channel version of the mapping cell 100 of FIG. 10. The mapping cells 150a-150n are connected in series with the source node S of one of the mapping cells 150a-150n connected to the drain node D of the next one of the mapping cells 150a-150n. The mapping cells 150a-150n include gate nodes G that are connected as input gate nodes INB1-INBn. The mapping cell 150a includes the input gate node INB1 and is connected to the output node OUT, and the mapping cell 150n includes the input gate node INBn and the reference node REF. Also, each of the mapping cells 150a-150n includes a corresponding one of the input gate nodes INB1-INBn. In addition, each of the mapping cells 150a-150n is attached to a gate node VmidB of the first transformation circuit 146.

In a second transformation circuit 152, the first mapping cell 148a remains a mapping cell.3, and the rest of the mapping cells 148b-148n are reduced to mapping cells 154b-154n that are each a p-channel version of the mapping cell.3b, i.e., a p-channel version of the mapping cell.3b 118 (shown in FIG. 12). The mapping cells 148a and 154b are connected in series with the source S of mapping cell 148a connected in series to the drain D of the mapping cell 154b. Also, the mapping cells 154b-154n are connected in series with the source S of one connected to the drain D of the next one of the mapping cells 154b-154n. The mapping cells 148a and a54b-154n include gate nodes G that are connected as input gate nodes INA1-INAn. The mapping cell 148a includes the input gate node INA1 and is connected to the output node OUT, and the mapping cell 154n includes the input gate INAn and the power node HVDD. Also, each of the mapping cells 154b-154n includes a corresponding one of the input gate nodes INA2-INAn. In addition, each of the mapping cells 148a and 154b-154n is attached to a gate node VmidA of the second transformation circuit 152.

Also, in the second transformation circuit 152, the first mapping cell 150a remains a mapping cell.3, and the rest of the mapping cells 150b-150n are reduced to mapping cells 156b-156n that are each an n-channel version of the mapping cell.3b, i.e., the mapping cell.3b 118 (shown in FIG. 12). The mapping cells 150a and 156b are connected in series with the source S of the mapping cell 150a connected in series to the drain D of the mapping cell 156b. Also, the mapping cells 156b-156n are connected in series with the source S of one connected to the drain D of the next one of the mapping cells 156b-156n. The mapping cells 150a and 156b-156n include gate nodes G that are connected as input gate nodes INB1-INBn. The mapping cell 150a includes the input gate node INB1 and is connected to the output node OUT, and the mapping cell 156n includes the input gate INBn and the reference node REF. Also, each of the mapping cells 156b-156n includes a corresponding one of the input gate nodes INB2-INBn. In addition, each of the mapping cells 150a and 156b-156n is attached to a gate node VmidB of the second transformation circuit 152.

In the first transformation circuit 146 and the second transformation circuit 152, the power node HVDD receives the high voltage of the IO domain, such as 1.2 volts, and each of the input gate nodes INA1-INAn and INB1-INBn is configured to receive a digital signal from 0 volts to the high voltage of the IO domain HVDD, such as 1.2 volts. In some embodiments, the voltage at the gate nodes VmidA is set to the high voltage of the IO domain HVDD minus the low voltage of the core domain LVDD, such as VmidA=1.2 volts-0.75 volts=0.45 volts, and the voltage at the gate nodes VmidB is set to the low voltage of the core domain LVDD, such as 0.75 volts.

In other embodiments, at least one and up to all the mapping cells 148a-148n is a p-channel version of the mapping cell.4, such as a p-channel version of the mapping cell 120 of FIG. 13 and at least one and up to all the mapping cells 150a-150n is an n-channel version of the mapping cell.4, such as the mapping cell 120 of FIG. 13. Also, in other embodiments, at least one and up to all the mapping cells 154b-154n is a p-channel version of the mapping cell.4b, such as a p-channel version of mapping cell 138 (shown in FIG. 15), and at least one and up to all the mapping cells 156b-156n is an n-channel version of the mapping cell.4b, such as the mapping cell 138 (shown in FIG. 15).

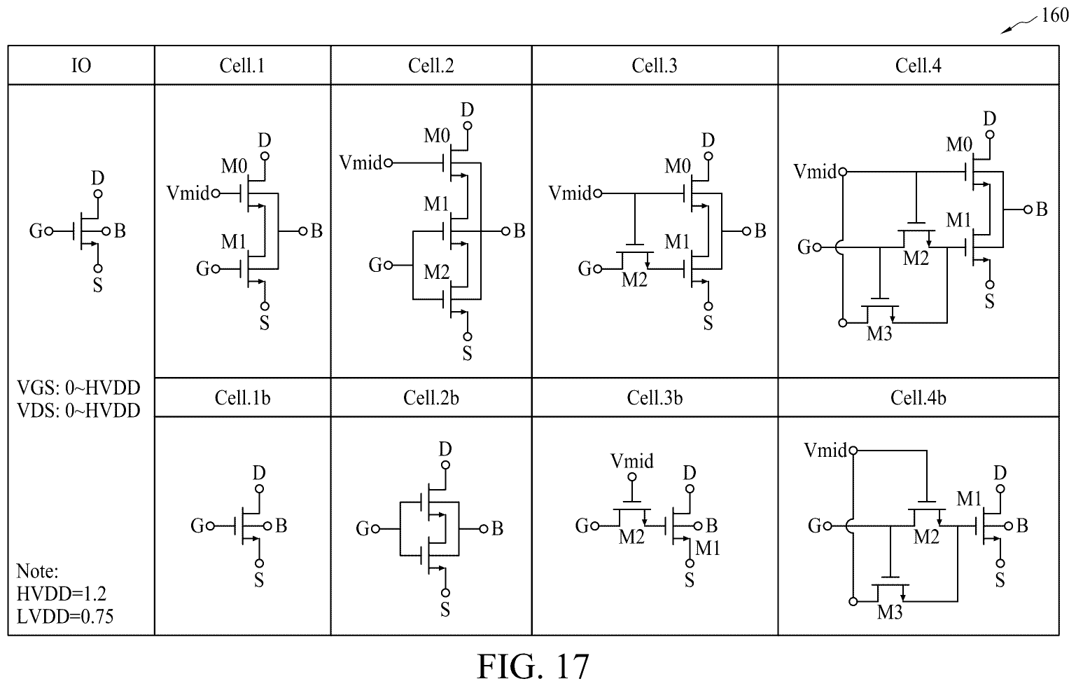

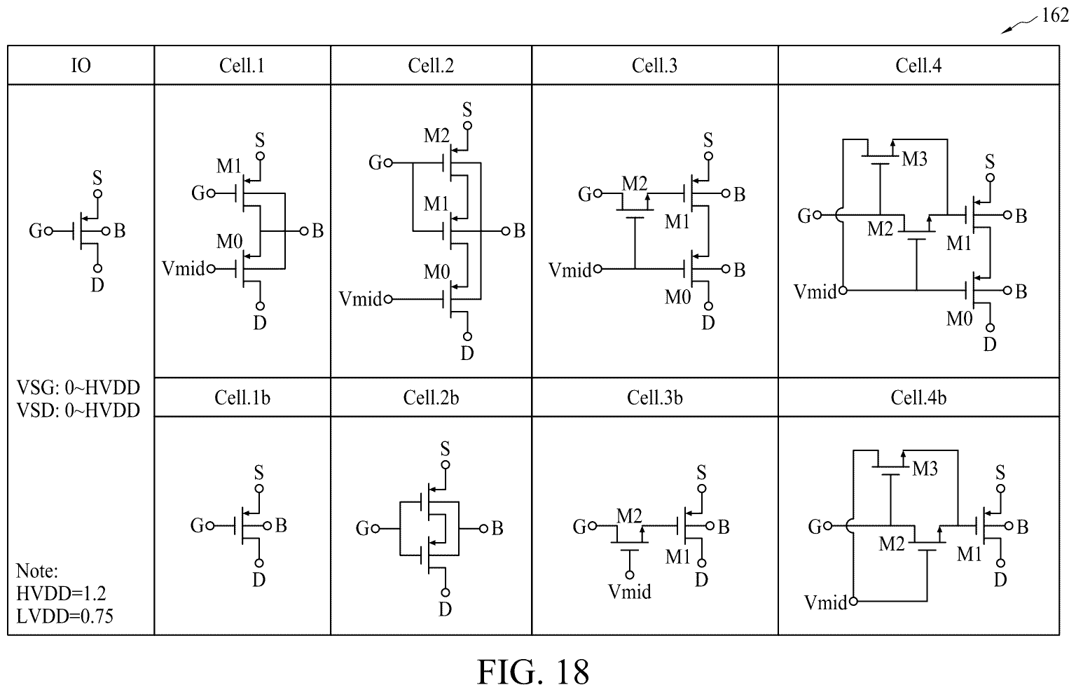

FIGS. 17 and 18 are diagrams schematically illustrating NMOS and PMOS mapping cells for the analog-like application mapping cells of mapping cell. 1, reduced mapping cell.1b, mapping cell.2, and reduced mapping cell.2b, and for the rail-to-rail and digital-like application mapping cells of mapping cell.3, reduced mapping cell.3b, mapping cell.4, and reduced mapping cell.4b.

FIG. 17 is a diagram schematically illustrating an NMOS electrical device for the IO domain and the NMOS mapping cells 160 for the analog-like applications and the rail-to-rail and digital-like applications, in accordance with some embodiments. The NMOS electrical device for the IO domain is configured to operate with gate-to-source voltages VGS from 0 volts to the high voltage of the IO domain HVDD and with drain-to-source voltages VDS from 0 volts to the high voltage of the IO domain HVDD, where in some embodiments, HVDD is equal to 1.2 volts and the low voltage of the core domain LVDD is equal to 0.75 volts. In some embodiments, the NMOS electrical device for the IO domain is like the NMOS electrical device 20 of FIG. 1.

The NMOS analog-like mapping cells include mapping cell. 1, mapping cell. 1b, mapping cell.2, and mapping cell.2b. In some embodiments, the NMOS mapping cell. 1 is like the mapping cell 22 of FIG. 2. In some embodiments, the NMOS mapping cell. 1b is like the mapping cell 38 (shown in FIG. 4). In some embodiments, the NMOS mapping cell.2 is like the mapping cell 40 of FIG. 5. In some embodiments, the NMOS mapping cell.2b is like the mapping cell 58 (shown in FIG. 7).

The NMOS mapping cell. 1 and the NMOS mapping cell. 1b are for general mapping with VGS less than or equal to LVDD and VDS less than or equal to HVDD. The NMOS mapping cell.2 and the mapping cell.2b are for mismatch-enhanced mapping with VGS less than or equal to LVDD and VDS less than or equal to HVDD.

The NMOS rail-to-rail and digital-like application mapping cells include mapping cell.3, mapping cell.3b, mapping cell.4, and mapping cell.4b. In some embodiments, the NMOS mapping cell.3 is like the mapping cell 100 of FIG. 10. In some embodiments, the NMOS mapping cell.3b is like the mapping cell 118 (shown in FIG. 12). In some embodiments, the NMOS mapping cell.4 is like the mapping cell 120 of FIG. 13. In some embodiments, the NMOS mapping cell.4b is like the mapping cell 138 (shown in FIG. 15).

The NMOS mapping cell.3 and the NMOS mapping cell.3b are for digital-like mapping with VGS less than or equal to HVDD and VDS less than or equal to HVDD. The NMOS mapping cell.4 and the NMOS mapping cell.4b are for enhanced digital-like mapping with VGS less than or equal to HVDD and VDS less than or equal to HVDD.

The gate node voltage Vmid can be generated in different ways. In some embodiments, Vmid is generated by one or more resistor ladders. In some embodiments, Vmid is generated via a low drop-out (LDO) regulator. In some embodiments, Vmid is received directly from a fixed input pin.

FIG. 18 is a diagram schematically illustrating a PMOS electrical device for the IO domain and PMOS mapping cells 162 for the analog-like applications and the rail-to-rail and digital-like applications, in accordance with some embodiments. The PMOS electrical device for the IO domain is configured to operate with source-to-gate voltages VSG from 0 volts to the high voltage of the IO domain HVDD and with source-to-drain voltages VSD from 0 volts to the high voltage of the IO domain HVDD, where in some embodiments, HVDD is equal to 1.2 volts and the low voltage of the core domain LVDD is equal to 0.75 volts. In some embodiments, the PMOS electrical device for the IO domain is the PMOS equivalent of the NMOS electrical device 20 of FIG. 1.

The PMOS analog-like mapping cells include mapping cell.1, mapping cell.1b, mapping cell.2, and mapping cell.2b. In some embodiments, the PMOS mapping cell.1 is the PMOS equivalent of the mapping cell 22 of FIG. 2. In some embodiments, the PMOS mapping cell. 1b is the PMOS equivalent of the mapping cell 38 (shown in FIG. 4). In some embodiments, the PMOS mapping cell.2 is the PMOS equivalent of the mapping cell 40 of FIG. 5. In some embodiments, the PMOS mapping cell.2b is the PMOS equivalent of the mapping cell 58 (shown in FIG. 7).

The PMOS mapping cell. 1 and the PMOS mapping cell. 1b are for general mapping with VSG less than or equal to LVDD and VSD less than or equal to HVDD. The PMOS mapping cell.2 and the mapping cell.2b are for mismatch-enhanced mapping with VSG less than or equal to LVDD and VSD less than or equal to HVDD.

The PMOS rail-to-rail and digital-like application mapping cells include mapping cell.3, mapping cell.3b, mapping cell.4, and mapping cell.4b. In some embodiments, the PMOS mapping cell.3 is the PMOS equivalent of the mapping cell 100 of FIG. 10. In some embodiments, the PMOS mapping cell.3b is the PMOS equivalent of the mapping cell 118 (shown in FIG. 12). In some embodiments, the PMOS mapping cell.4 is the PMOS equivalent of the mapping cell 120 of FIG. 13. In some embodiments, the PMOS mapping cell.4b is the PMOS equivalent of the mapping cell 138 (shown in FIG. 15).

The PMOS mapping cell.3 and the PMOS mapping cell.3b are for digital-like mapping with VSG less than or equal to HVDD and VSD less than or equal to HVDD. The PMOS mapping cell.4 and the PMOS mapping cell.4b are for enhanced digital-like mapping with VSG less than or equal to HVDD and VSD less than or equal to HVDD.

The gate node voltage Vmid can be generated in different ways. In some embodiments, Vmid is generated by one or more resistor ladders. In some embodiments, Vmid is generated via a low drop-out (LDO) voltage regulator. In some embodiments, Vmid is received directly from a fixed input pin.

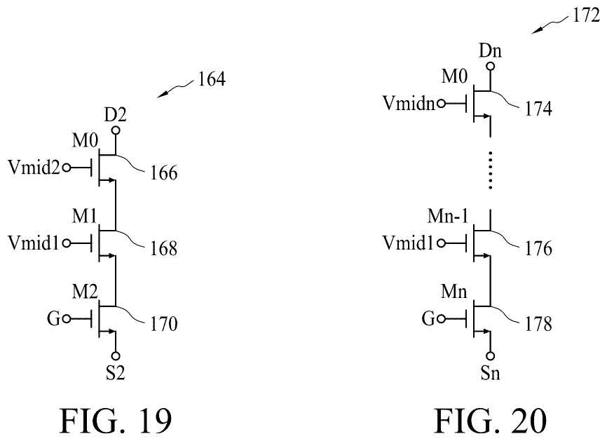

FIG. 19 is a diagram schematically illustrating an NMOS mapping cell 164 that includes two cascode protection transistors M0 166 and M1 168, in accordance with some embodiments. The mapping cell 164 includes the two cascode protection transistors M0 166 and M1 168 and a third transistor M2 170. Each of the transistors M0 166, M1 168, and M2 170 is an n-channel MOSFET that meets the design rule limitations of the core domain. In some embodiments, the mapping cell 164 is configured to replace the electrical device 20 of FIG. 1 in the IO domain of an integrated circuit.

The mapping cell 164, referred to as an NMOS mapping cell.1.c2, includes a drain node D2, a gate node G, a source node S2, a gate node Vmid1 for biasing the transistor M1 168, and a gate node Vmid2 for biasing the transistor M0 166. The transistor M0 166 includes the drain node D2, the gate node Vmid2, and a source node that is connected in series to a drain node of the transistor M1 168. The transistor M1 168 includes the gate node Vmid1 and a source node that is connected in series to a drain node of the transistor M2 170. The transistor M2 170 includes the gate node G and the source node S2. In some embodiments, each of the transistors M0 166, M1 168, and M2 170 includes a body node B. In some embodiments, the drain node D2, the gate node G, the source node S2, and the body node B are like the nodes of the electrical device 20 of FIG. 1.

In analog operation, the cascode protection transistors M0 166 and 168 are biased to prevent transistor M2 170 from being broken down or damaged when the higher voltage of the IO domain is applied to the drain node D2 of the mapping cell 164. Also, the voltage applied to the gate node G of transistor M2 170 is an analog signal. Thus, the mapping cell 164 can replace the electrical device 20 in the IO domain without breaking down or damaging the transistors M0 166, M1 168, and M2 170.

FIG. 20 is a diagram schematically illustrating an NMOS mapping cell 172 that includes n cascode protection transistors M0 174, . . . . Mn-1 176, in accordance with some embodiments. The mapping cell 172 includes the n cascode protection transistors M0 174, . . . . Mn-1 176 and transistor Mn 178. Each of the transistors M0 174, . . . . Mn-1 176, and Mn 178 is an n-channel MOSFET that meets the design rule limitations of the core domain. In some embodiments, the mapping cell 172 is configured to replace the electrical device 20 of FIG. 1 in the IO domain of an integrated circuit.

The mapping cell 172, referred to as an NMOS mapping cell.1.cn, includes a drain node Dn, a gate node G, a source node Sn, a gate node Vmid1 for biasing the transistor Mn-1 176, and a gate node Vmidn for biasing the transistor M0 174. The transistor M0 174 includes the drain node Dn, the gate node Vmidn, and a source node that is connected in series to a drain node of the next transistor down to transistor Mn-1 176. The transistor Mn-1 176 includes the gate node Vmid1 and a source node that is connected in series to a drain node of the transistor Mn 178. The transistor Mn 178 includes the gate node G and the source node Sn. In some embodiments, each of the transistors M0 174, . . . . Mn-1 176, and Mn 178 includes a body node B. In some embodiments, the drain node Dn, the gate node G, the source node Sn, and the body node B are like the nodes of the electrical device 20 of FIG. 1.

In analog operation, the cascode protection transistors M0 174, . . . . Mn-1 176 are biased to prevent transistor Mn 178 from being broken down or damaged when the higher voltage of the IO domain is applied to the drain node Dn of the mapping cell 172. Also, the voltage applied to the gate node G of transistor Mn 178 is an analog signal. Thus, the mapping cell 172 can replace the electrical device 20 in the IO domain without breaking down or damaging the transistors M0 174, . . . . Mn-1 176, and Mn 178.

The NMOS mapping cells with multiple cascode protection transistors can include up to n cascode protection transistors in mapping cells referred to as NMOS mapping cell1.c2 up to NMOS mapping cell.1.cn. The increased number of cascode protection transistors is based on the higher voltage in the IO domain. The allowable VDS maximum is greater with more cascode protection transistors, such that VDSn> . . . VDS2>VDS1 and Vmidn> . . . Vmid2>Vmid1.

The inclusion of more than one cascode protection transistor is a feature that can be extended to each of the NMOS mapping cells disclosed herein, including the NMOS mapping cell.1, the NMOS mapping cell.2, the NMOS mapping cell.3, and the NMOS mapping cell.4. The cascode protection transistors are biased at the gate node Vmid to protect the mapping cells from high VDS voltages, such as the high voltages in the IO domain. Also, this feature of more than one cascode protection transistor can be used in NMOS mapping cells and in PMOS mapping cells.

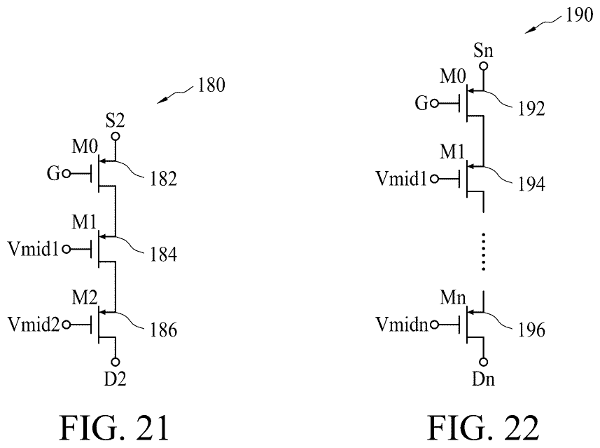

FIG. 21 is a diagram schematically illustrating a PMOS mapping cell 180 that includes a transistor M0 182 and two cascode protection transistors M1 184 and M2 186, in accordance with some embodiments. Each of the transistors M0 182, M1 184, and M2 186 is a p-channel MOSFET that meets the design rule limitations of the core domain. In some embodiments, the mapping cell 180 is configured to replace the electrical device 20 of FIG. 1 in the IO domain of an integrated circuit.

The mapping cell 180, referred to as a PMOS mapping cell.1.c2, includes a source node S2, a gate node G, a drain node D2, a gate node Vmid1 for biasing the transistor M1 184, and a gate node Vmid2 for biasing the transistor M2 186. The transistor M0 182 includes the source node S2, the gate node G, and a drain node that is connected in series to a source node of the transistor M1 184. The transistor M1 184 includes the gate node Vmid1 and a drain node that is connected in series to a source node of the transistor M2 186. The transistor M2 186 includes the gate node Vmid2 and the drain node D2. In some embodiments, each of the transistors M0 182, M1 184, and M2 186 includes a body node B.

In analog operation, the cascode protection transistors M1 184 and M2 186 are biased to prevent transistor M0 182 from being broken down or damaged when the higher voltage of the IO domain is applied to the mapping cell 180. Also, the voltage applied to the gate node G of transistor M0 182 is an analog signal. Thus, the mapping cell 180 can replace electrical devices in the IO domain without breaking down or damaging the transistors M0 182, M1 184, and M2 186.

FIG. 22 is a diagram schematically illustrating a PMOS mapping cell 190 that includes a transistor M0 192 and n cascode protection transistors M1 194, . . . . Mn 196, in accordance with some embodiments. Each of the transistors M0 192 and M1 194, . . . . Mn 196 is a p-channel MOSFET that meets the design rule limitations of the core domain. In some embodiments, the mapping cell 190 is configured to replace the electrical device 20 of FIG. 1 in the IO domain of an integrated circuit.

The mapping cell 190, referred to as a PMOS mapping cell.1.cn, includes a source node Sn, a gate node G, a drain node Dn, a gate node Vmid1 for biasing the transistor M1 194, and a gate node Vmidn for biasing the transistor Mn 196. The transistor M0 192 includes the source node Sn, the gate node G, and a drain node that is connected in series to a source node of transistor M1 194. The transistor M1 194 includes the gate node Vmid1 and a drain node that is connected in series to a source node of the next transistor down to the transistor Mn 196. The transistor Mn 196 includes the gate node Vmidn and the drain node Dn. In some embodiments, each of the transistors M0 192 and M1 194, . . . . Mn 196 includes a body node B.

In analog operation, the cascode protection transistors M1 194, . . . . Mn 196 are biased to prevent transistor M0 192 from being broken down or damaged when the higher voltage of the IO domain is applied to the mapping cell 190. Also, the voltage applied to the gate node G of transistor M0 192 is an analog signal. Thus, the mapping cell 190 can replace the electrical devices in the IO domain without breaking down or damaging the transistors M0 192 and M1 194, . . . . Mn 196.

The PMOS mapping cells with multiple cascode protection transistors can include up to n cascode protection transistors in mapping cells referred to as PMOS mapping cell1.c2 up to PMOS mapping cell.1.cn. The increased number of cascode protection transistors is based on the higher voltage in the IO domain. The allowable VSD maximum is greater with more cascode protection transistors, such that VSDn> . . . VSD2>VSD1 and Vmid1> . . . Vmid2>Vmidn.

The inclusion of more than one cascode protection transistor is a feature that can be extended to each of the PMOS mapping cells, including the PMOS mapping cell.1, the PMOS mapping cell.2, the PMOS mapping cell.3, and the PMOS mapping cell.4. The cascode protection transistors are biased at the gate node Vmid to protect the mapping cells from high VSD voltages, such as the high voltages in the IO domain.

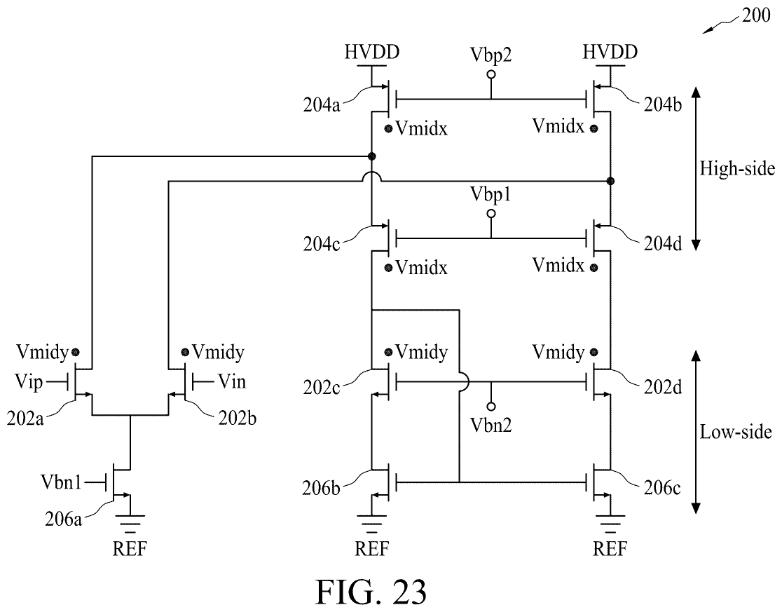

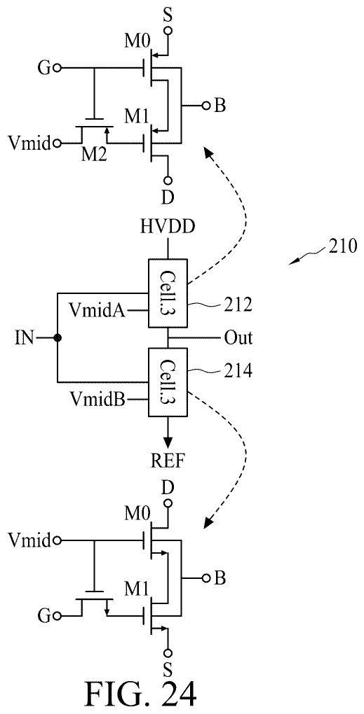

FIG. 23 is a diagram schematically illustrating an operational transconductance amplifier (OTA) 200, in accordance with some embodiments. The OTA 200 is a mapping example of an analog application.

The OTA 200 includes four NMOS mapping cells 202a-202d, four PMOS mapping cells 204a-204d, and three NMOS transistors 206a-206c. Each of the NMOS mapping cells 202a-202d can be any one of the NMOS mapping cells of mapping cell.1, mapping cell.2, mapping cell.3, and mapping cell.4, and each of the PMOS mapping cells 204a-204d can be any one of the PMOS mapping cells of mapping cell.1, mapping cell.2, mapping cell.3, and mapping cell.4. Also, in some embodiments, the NMOS mapping cells 202a-202d can include the reduced NMOS mapping cells of mapping cell. 1b, mapping cell.2b, mapping cell.3b, and mapping cell.4b and extended versions of the NMOS mapping cells, and the PMOS mapping cells 204a-204d can include the reduced PMOS mapping cells of mapping cell.1b, mapping cell.2b, mapping cell.3b, and mapping cell.4b and extended versions of the PMOS mapping cells.

The OTA 200 is connected to power HVDD and a reference REF, such as ground, to operate in the IO domain at the high voltage of the IO domain HVDD. Each of the NMOS mapping cells 202a-202d includes a gate node Vmid for receiving the voltage Vmidy and each of the PMOS mapping cells 204a-204d includes a gate node Vmid for receiving the voltage Vmidx. In some embodiments, HVDD is equal to 1.2 volts, Vmidx is equal to 0.45 volts, and/or Vmidy is equal to 0.75 volts.

The NMOS mapping cells 202a and 202b receive the gate bias voltages Vip and Vin, respectively, at the gated nodes G of the mapping cells 202a and 202b, and the NMOS transistor 206a receives the gate bias voltage Vbn1 for biasing the transistor 206a. The NMOS mapping cells 202c and 202d receive the gate bias voltage Vbn2 at the gate nodes G of the mapping cells 202c and 202d. Also, the PMOS mapping cells 204a and 204b receive the gate bias voltage Vbp2 at the gate nodes G of the mapping cells 204a and 204b and the PMOS mapping cells 204c and 204d receive the gate bias voltage Vbp1 at the gate nodes G of the mapping cells 204c and 204d. Thus, the OTA 200 is configured to operate in the IO domain at the high voltage of the IO domain HVDD, while receiving core domain input voltages, such as gate bias voltages Vip and Vin.

FIG. 24 is a diagram schematically illustrating an inverter 210, in accordance with some embodiments. The inverter 210 is a mapping example of a rail-to-rail digital application. The inverter 210 includes a PMOS mapping cell 212 and an NMOS mapping cell 214.

The PMOS mapping cell 212 is a mapping cell.3, such as a PMOS version of mapping cell 100 of FIG. 10, and the NMOS mapping cell 214 is a mapping cell.3, such as the NMOS mapping cell 100 of FIG. 10. In other embodiments, the PMOS mapping cell 212 can be a mapping cell.4, such as a PMOS version of mapping cell 120 of FIG. 13 and, in other embodiments, the NMOS mapping cell 214 can be a mapping cell.4, such as the NMOS mapping cell 120 of FIG. 13. Also, in some embodiments, the PMOS mapping cell 212 can include the reduced PMOS mapping cells of mapping cell.3b and mapping cell.4b and extended versions of the PMOS mapping cells, and the NMOS mapping cell 214 can include the reduced NMOS mapping cells of mapping cell.3b and mapping cell.4b and extended versions of the NMOS mapping cells.

The inverter 210 is connected to power HVDD and a reference REF, such as ground, to operate in the IO domain at the high voltage of the IO domain HVDD. The PMOS mapping cell 212 includes a gate node Vmid for receiving the voltage VmidA and the NMOS mapping cell 214 includes a gate node Vmid for receiving the voltage VmidB. In some embodiments, HVDD is equal to 1.2 volts, VmidA is equal to HVDD minus LVDD or 1.2 volts minus 0.75 volts=0.45 volts, and/or VmidB is equal to LVDD or 0.75 volts.

A gate node G of the PMOS mapping cell 212 is connected to a gate node G of the NMOS mapping cell 214 at input IN. Also, a drain node D of the PMOS mapping cell 212 is connected to a drain node D of the NMOS mapping cell 214 at output OUT. The input IN receives a digital voltage from 0 volts to the high voltage of the IO domain HVDD or 1.2 volts, and the output OUT provides a digital output signal from 0 volts to the high voltage of the IO domain HVDD or 1.2 volts. Thus, the inverter 210 is configured to operate in the IO domain at the high voltage of the IO domain HVDD, while receiving IO domain input voltages at input IN and providing IO domain output voltages at output OUT.

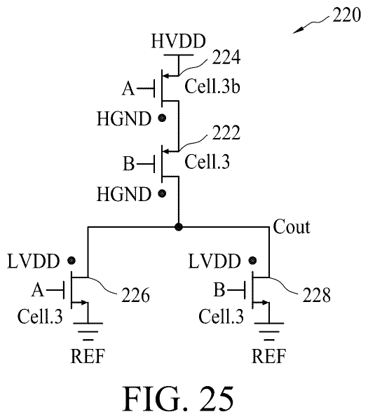

FIG. 25 is a diagram schematically illustrating a NAND gate 220, in accordance with some embodiments. The NAND gate 220 is configured to receive two input signals A and B and provide a NAND gate output signal at output Cout. The NAND gate 220 is a mapping example of a rail-to-rail digital application.

The NAND gate 220 includes two PMOS mapping cells 222 and 224 and two NMOS mapping cells 226 and 228. The PMOS mapping cell 222 is a mapping cell.3, such as a PMOS version of mapping cell 100 of FIG. 10, and the PMOS mapping cell 224 is a reduced mapping cell.3b, such as a PMOS version of mapping cell.3b 118 (shown in FIG. 12). Each of the NMOS mapping cells 226 and 228 is a mapping cell.3, such as mapping cell 100 of FIG. 10. In other embodiments, the PMOS mapping cell 222 is a mapping cell.4, such as a PMOS version of mapping cell 120 of FIG. 13, and the PMOS mapping cell 224 is a reduced mapping cell.4b, such as a PMOS version of mapping cell.4b 138 (shown in FIG. 15). Also, in other embodiments, one or more of the NMOS mapping cells 226 and 288 is a mapping cell.4, such as the NMOS mapping cell 120 of FIG. 13. In addition, in some embodiments, the PMOS mapping cell 222 can include the reduced PMOS mapping cells of mapping cell.3b and mapping cell.4b and extended versions of the PMOS mapping cells, and the NMOS mapping cells 226 and 228 can include the reduced NMOS mapping cells of mapping cell.3b and mapping cell.4b and extended versions of the NMOS mapping cells.

The NAND gate 220 is connected to power HVDD and a reference REF, such as ground, to operate in the IO domain at the high voltage of the IO domain HVDD. Each of the PMOS mapping cells 222 and 224 includes a gate node Vmid for receiving a high ground gate voltage HGND, and each of the NMOS mapping cells 226 and 228 includes a gate node Vmid for receiving the gate voltage of LVDD. In some embodiments, HVDD is equal to 1.2 volts, HGND is equal to 0.45 volts, and LVDD is equal to 0.75 volts.

A gate node G of the PMOS mapping cell 224 and a gate node G of the NMOS mapping cell 226 receive the input signal A, and a gate node G of the PMOS mapping cell 222 and a gate node G of the NMOS mapping cell 228 receive the input signal B. Also, a source node of the PMOS mapping cell 224 receives power HVDD and a drain node of the mapping cell 224 is connected to a source node of the mapping cell 222. A drain node of the mapping cell 222 is connected to each of the drain nodes of the NMOS mapping cells 226 and 228 at output Cout and each of the source nodes of the mapping cells 226 and 228 is connected to the reference REF.

The input signals A and B are digital signals that range from 0 volts to the high voltage of the IO domain HVDD or 1.2 volts, and the output Cout provides a digital output signal that ranges from 0 volts to the high voltage of the IO domain HVDD or 1.2 volts. Thus, the inverter 220 is configured to operate in the IO domain at the high voltage of the IO domain HVDD, while receiving IO domain input signals A and B and providing an IO domain output voltage at output Cout.

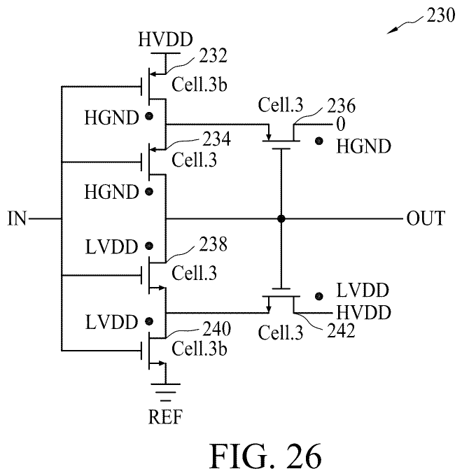

FIG. 26 is a diagram schematically illustrating a Schmitt trigger 230, in accordance with some embodiments. The Schmitt trigger 230 is configured to receive an input signal IN and to provide an output signal at output OUT. The Schmitt trigger 230 is a mapping example of a rail-to-rail digital application.

The Schmitt trigger 230 includes three PMOS mapping cells 232, 234, and 236 and three NMOS mapping cells 238, 240, and 242. Each of the PMOS mapping cells 234 and 236 is a mapping cell.3, such as a PMOS version of mapping cell 100 of FIG. 10, and the PMOS mapping cell 232 is a reduced mapping cell.3b, such as a PMOS version of mapping cell.3b 118 (shown in FIG. 12). Each of the NMOS mapping cells 238 and 242 is a mapping cell.3, such as mapping cell 100 of FIG. 10, and the NMOS mapping cell 240 is a reduced mapping cell.3b, such as mapping cell.3b 118 (shown in FIG. 12). In other embodiments, one or more of the PMOS mapping cells 234 and 236 is a mapping cell.4, such as a PMOS version of mapping cell 120 of FIG. 13, and the PMOS mapping cell 232 is a reduced mapping cell.4b, such as a PMOS version of mapping cell.4b 138 (shown in FIG. 15). Also, in other embodiments, one or more of the NMOS mapping cells 238 and 242 is a mapping cell.4, such as the NMOS mapping cell 120 of FIG. 13, and the NMOS mapping cell 240 is a reduced mapping cell.4b, such as mapping cell.4b 138 (shown in FIG. 15). In addition, in some embodiments, the PMOS mapping cells 234 and 236 can include the reduced PMOS mapping cells of mapping cell.3b and mapping cell.4b and extended versions of the PMOS mapping cells, and the NMOS mapping cells 238 and 242 can include the reduced NMOS mapping cells of mapping cell.3b and mapping cell.4b and extended versions of the NMOS mapping cells.

The Schmitt trigger 230 is connected to power HVDD and a reference REF, such as ground, to operate in the IO domain at the high voltage of the IO domain HVDD. Each of the PMOS mapping cells 232, 234, and 236 includes a gate node Vmid for receiving a high ground gate voltage HGND, and each of the NMOS mapping cells 238, 240, and 242 includes a gate node Vmid for receiving the gate voltage of LVDD. In some embodiments, HVDD is equal to 1.2 volts, HGND is equal to 0.45 volts, and LVDD is equal to 0.75 volts.

In the Schmitt trigger 230, a source node of the PMOS mapping cell 232 receives power HVDD and a drain node of the mapping cell 232 is connected to a source node of the mapping cell 234 and a source node of the mapping cell 236. A drain node of the mapping cell 236 is connected to 0 volts. A drain node of the mapping cell 234 is connected to a drain node of the NMOS mapping cell 238 and to the gate nodes of the mapping cells 236 and 242 at the output OUT. A drain node of the mapping cell 242 is connected to receive the high voltage of the IO domain HVDD. A source node of the NMOS mapping cell 238 is connected to a drain node of the mapping cell 240 and a source node of the mapping cell 242. The source node of the mapping cell 240 is connected to the reference REF. Gate nodes G of each of the PMOS mapping cells 232 and 234 and each of the NMOS mapping cells 238 and 240 receive the input signal IN.

The input signal IN is a digital signal that ranges from 0 volts to the high voltage of the IO domain HVDD, such as 1.2 volts, and the output OUT provides a digital output signal that ranges from 0 volts to the high voltage of the IO domain HVDD, such as 1.2 volts. Thus, the Schmitt trigger 230 is configured to operate in the IO domain at the high voltage of the IO domain HVDD, while receiving IO domain input signal IN and providing an IO domain output voltage at output OUT.

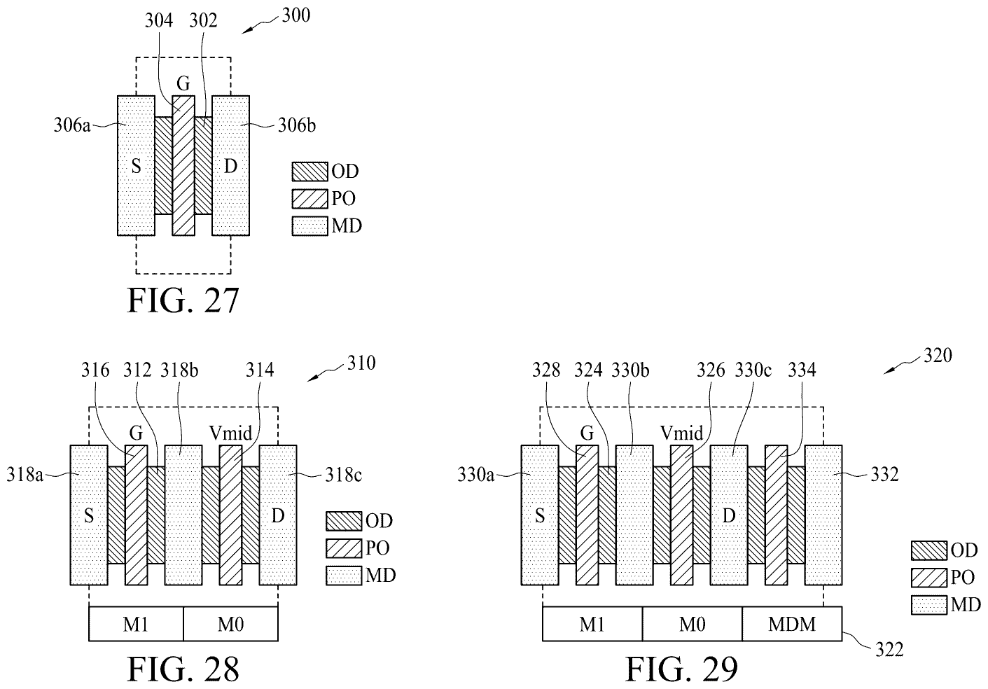

FIG. 27 is a diagram schematically illustrating a semiconductor structure 300 of the electrical device 20 of FIG. 1, in accordance with some embodiments. The semiconductor structure 300 is configured to operate in the IO domain of the integrated circuit. The semiconductor structure 300 includes an oxide diffusion (OD) region 302, a polycrystalline silicon (PO) gate 304 situated over the OD region 302, a source metal over diffusion (MD) layer 306a situated over a source region and a drain MD layer 306b situated over a drain region.

Throughout the current application, an OD region, such as the OD region 302, defines the active area of a transistor (or transistors) including the drain region, the source region, and the channel region that is under the gate of the transistor. Also, throughout this application, source MD layers are situated over source/drain regions and drain MD layers are situated over source/drain regions, where source/drain regions may refer to a source or a drain, individually or collectively dependent upon the context.

FIG. 28 is a diagram schematically illustrating a semiconductor structure 310 of the mapping cell 22 of FIG. 2, in accordance with some embodiments. The semiconductor structure 310 is configured to operate in the IO domain of the integrated circuit.

The semiconductor structure 310 includes an OD region 312, a PO gate Vmid 314 that is situated over the OD region 312, a PO gate G 316 that is situated over the OD region 312, a source MD layer 318a, a combined source and drain MD layer 318b, and a drain MD layer 318c.

The semiconductor structure 310 includes transistor M0 abutted with transistor M1 of the mapping cell 22 of FIG. 2. The transistor M0 includes the drain MD layer 318c, the PO gate Vmid 314, and the combined source and drain MD layer 318b. The transistor M1 includes the combined source and drain MD layer 318b, the PO gate G 316, and the source MD layer 318a. Also, the drain MD layer 318c and the source MD layer 318a are situated at each end of the semiconductor structure 310 as in the semiconductor structure 300.

FIG. 29 is a diagram schematically illustrating a semiconductor structure 320 of the mapping cell 22 of FIG. 2, which includes a dummy insertion structure (MDM) 322, in accordance with some embodiments. The semiconductor structure 320 includes an OD region 324, a PO gate Vmid 326, a PO gate G 328, a source MD layer 330a, a combined source and drain MD layer 330b, and a drain MD layer 330c. The semiconductor structure 320 further includes a dummy MD layer 332 and a dummy PO gate 334 over the OD region 324.

The semiconductor structure 320 includes transistor M0 abutted with transistor M1 of the mapping cell 22 of FIG. 2. The transistor M0 includes the drain MD layer 330c, the PO gate Vmid 326, and the combined source and drain MD layer 330b. The transistor M1 includes the combined source and drain MD layer 330b, the PO gate G 328, and the source MD layer 330a. The MDM 322 abuts the transistor M0 and includes the drain MD layer 330c, the dummy PO gate 334, and the dummy MD layer 332.

The MDM 322 does not provide transistor functionality in the semiconductor structure 320. Instead, the MDM 322 is included for heat radiation. The MDM 322 can be situated at the drain node D and/or at the source node S. In some embodiments, the semiconductor structure 320 includes a single MDM 322 and, in some embodiments, the semiconductor structure 320 includes multiple MDM 322.

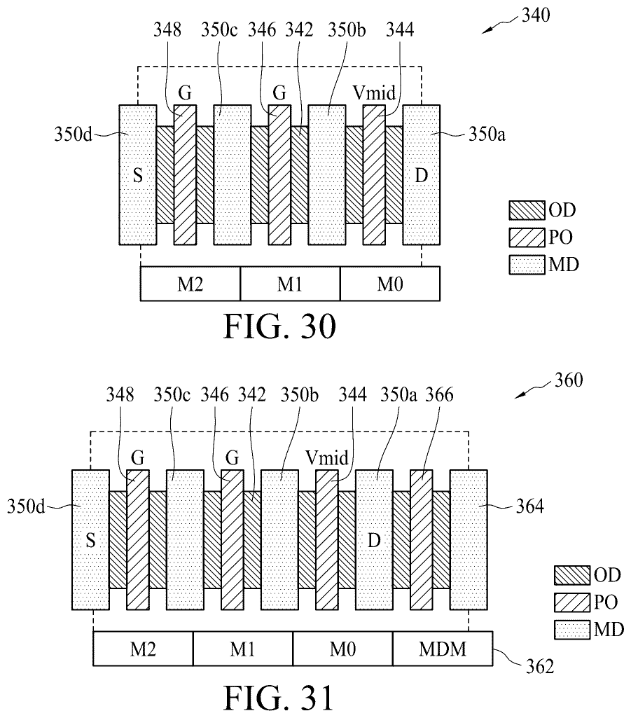

FIG. 30 is a diagram schematically illustrating a semiconductor structure 340 of the mapping cell 40 of FIG. 5, in accordance with some embodiments. The semiconductor structure 340 is configured to operate in the IO domain of the integrated circuit.

The semiconductor structure 340 includes an OD region 342, a PO gate Vmid 344, a first PO gate G 346, a second PO gate G 348, a drain MD layer 350a, a first combined source and drain MD layer 350b, a second combined source and drain MD layer 350c, and a source MD layer 350d.

The semiconductor structure 340 includes transistor M0 abutted with transistor M1, and transistor M1 abutted with transistor M2 of the mapping cell 40 of FIG. 5. The transistor M0 includes the drain MD layer 350a, the PO gate Vmid 344, and the first combined source and drain MD layer 350b. The transistor M1 includes the first combined source and drain MD layer 350b, the first PO gate G 346, and the second combined source and drain MD layer 350c. The transistor M2 includes the second combined source and drain MD layer 350c, the second PO gate G 348, and the source MD layer 350d. Also, the drain MD layer 350a and the source MD layer 350d are situated at each end of the semiconductor structure 340 as in the semiconductor structure 300.

FIG. 31 is a diagram schematically illustrating a semiconductor structure 360 of the mapping cell 40 of FIG. 5, which includes an MDM 362, in accordance with some embodiments. The semiconductor structure 360 includes the semiconductor structure 340 of the OD region 342, the PO gate Vmid 344, the first PO gate G 346, the second PO gate G 348, the drain MD layer 350a, the first combined source and drain MD layer 350b, the second combined source and drain MD layer 350c, and the source MD layer 350d. In addition, the semiconductor structure 360 includes a dummy MD layer 364 and a dummy PO gate 366 over the OD region 342.

The semiconductor structure 360 includes transistor M0 abutted with transistor M1, and transistor M1 abutted with transistor M2 of the mapping cell 40 of FIG. 5. The transistor M0 includes the drain MD layer 350a, the PO gate Vmid 344, and the first combined source and drain MD layer 350b. The transistor M1 includes the first combined source and drain MD layer 350b, the first PO gate G 346, and the second combined source and drain MD layer 350c. The transistor M2 includes the second combined source and drain MD layer 350c, the second PO gate G 348, and the source MD layer 350d. The MDM 362 abuts the transistor M0 and includes the drain MD layer 350a, the dummy PO gate 366 and the dummy MD layer 364.

The MDM 362 does not provide transistor functionality in the semiconductor structure 320. Instead, the MDM 362 is included for heat radiation. The MDM 362 can be situated at the drain node D and/or at the source node S. In some embodiments, the semiconductor structure 360 includes a single MDM 362 and, in some embodiments, the semiconductor structure 360 includes multiple MDM 362.

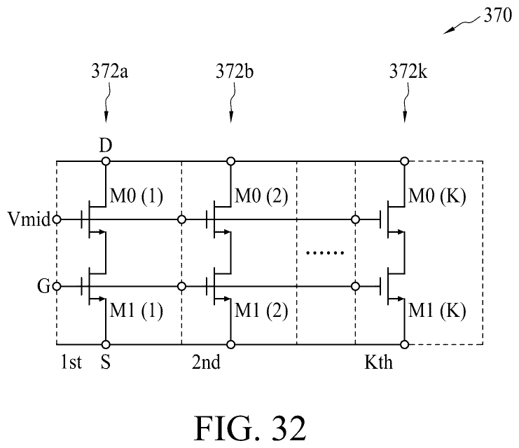

FIG. 32 is a diagram schematically illustrating a parallel combination of mapping cells 370, in accordance with some embodiments. The parallel combination of mapping cells 370 includes mapping cells 372a, 372b, . . . to 372K where, in some embodiments, each of the mapping cells 372a, 372b, . . . to 372K is like the mapping cell 22 of FIG. 2.

The mapping cell 372a includes transistor M0(1) connected in series to transistor M1(1), the mapping cell 372b includes transistor M0(2) connected in series to transistor M1(2), down to the mapping cell 372K includes transistor M0(K) connected in series to transistor M1(K). Each of the transistors M0 is connected to the drain node D and the gate node Vmid and includes a source node connected in series to a drain node of a corresponding one of the transistors M1. Each of the transistors M1 is connected to the source node S and the gate node G of the parallel combination of mapping cells 370.

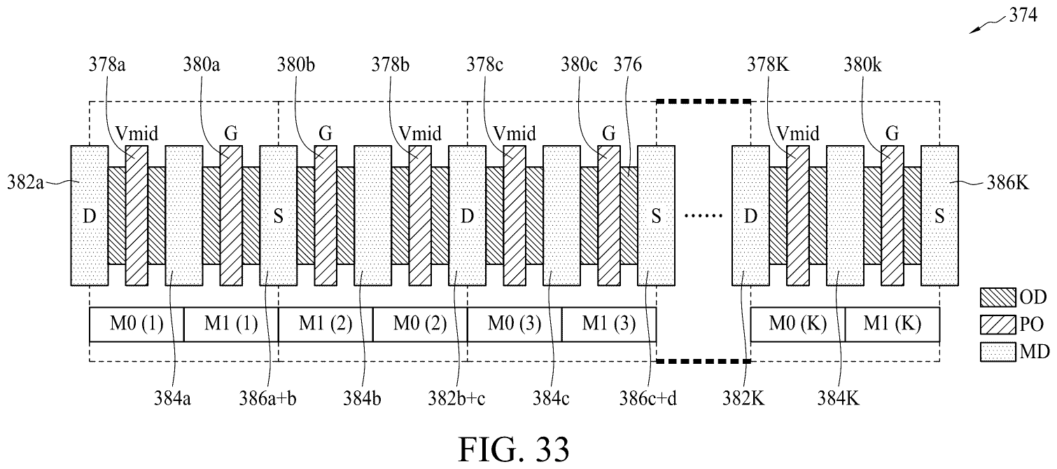

FIG. 33 is a diagram schematically illustrating a semiconductor structure 374 of the parallel combination of mapping cells 370 of FIG. 32, in accordance with some embodiments. The semiconductor structure 374 is configured to operate in the IO domain of the integrated circuit.

The semiconductor structure 374 includes an OD region 376, PO gates Vmid 378a-378K, PO gates G 380a-380K, drain MD layers 382a-382K, combined source and drain MD layers 384a-384K, and source MD layers 386a-386K.

The semiconductor structure 374 includes transistor M0(1) that is abutted with transistor M1(1) that is abutted with transistor M1(2) that is abutted with transistor M0(2) that is abutted with transistor M0(3) that is abutted with transistor M1(3) and so on, down to transistor M0(K) that is abutted with transistor M1(K).

The transistor M0(1) includes the drain MD layer 382a, the PO gate Vmid 378a, and the combined source and drain MD layer 384a. The transistor M1(1) includes the combined source and drain MD layer 384a, the PO gate G 380a, and the source MD layer 386a that is also the source MD layer 386b. The transistor M1(2) includes the source MD layer 386b, the PO gate G 380b, and the combined source and drain MD layer 384b. The transistor M0(2) includes the combined source and drain MD layer 384b, the PO gate Vmid 378b, and the drain MD layer 382b that is also the drain MD layer 382c. The transistor M0(3) includes the drain MD layer 382c, the PO gate Vmid 378c, and the combined source and drain MD layer 384c. The transistor M1(3) includes the combined source and drain MD layer 384c, the PO gate G 380c, and the source MD layer 386c that is also the source MD layer 386d. This continues down to the transistor M0(K) that includes the drain MD layer 382K, the PO gate Vmid 378K, and the combined source and drain MD layer 384K, and the transistor M1(K) that includes the combined source and drain MD layer 384K, the PO gate G 380K, and the source MD layer 386K. In some embodiments, the drain MD layers 382a-382K and the source MD layers 386a-386K are situated at the same positions in the semiconductor structure 374 as in a semiconductor structure of the parallel combination of IO electrical devices, such as electrical device 20 of FIG. 1.

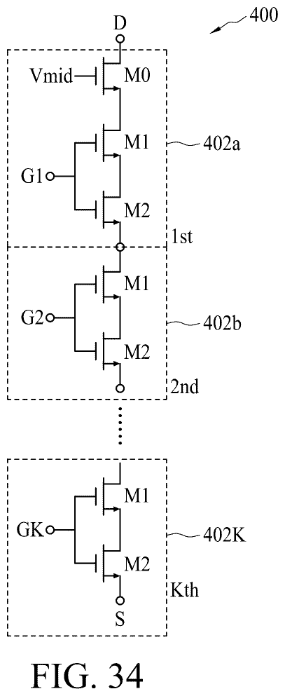

FIG. 34 is a diagram schematically illustrating a series combination of mapping cells 400, in accordance with some embodiments. The series combination of mapping cells 400 includes mapping cells 402a, 402b, . . . to 402K where, in some embodiments, mapping cell 402a is like mapping cell 40 of FIG. 5, which is a mapping cell.2, and each of the mapping cells 402b to 402K is like mapping cell 58 (shown in FIG. 7), which is a mapping cell.2b (shown in FIG. 7).

The mapping cell 402a includes a transistor M0 with a drain node D, a gate node Vmid, and a source node connected in series to a drain node of transistor M1 that has a source node connected in series to a drain node of transistor M2. A source node of transistor M2 of mapping cell 402a is connected in series to a drain node of mapping cell 402b and so on, down to mapping cell 400K that has a source node S. Each of the mapping cells 402a-402K includes a corresponding gate node G1-GK that is connected to each of the transistors M1 and M2 in the mapping cell.

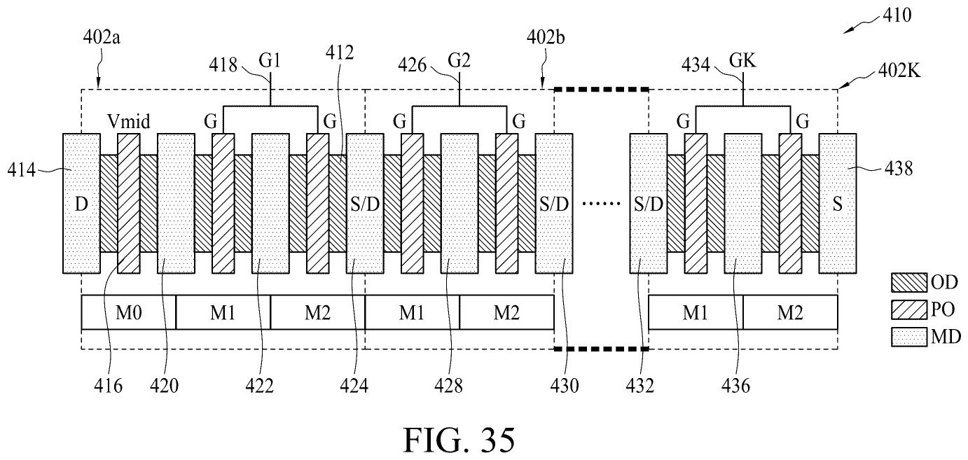

FIG. 35 is a diagram schematically illustrating a semiconductor structure 410 of the series combination of mapping cells 400 of FIG. 34, in accordance with some embodiments. The semiconductor structure 410 is configured to operate in the IO domain of the integrated circuit.

The semiconductor structure 410 includes mapping cell 402a abutting mapping cell 402b and so on, down to mapping cell 402K. The semiconductor structure 410 includes an OD region 412 and the mapping cell 402a includes a drain node D 414, a PO gate Vmid 416, a gate node G1 418 that is connected to each gate node G of the transistors M1 and M2 in the mapping cell 402a, a first combined source and drain MD layer 420, a second combined source and drain MD layer 422, and a source/drain node S/D 424 that is a source of mapping cell 402a and a drain of mapping cell 402b. The mapping cell 402b includes the source/drain node S/D 424, a gate node G2 426 that is connected to each of the gate nodes G of the transistors M1 and M2 in the mapping cell 402b, a combined source and drain MD layer 428, and a source/drain node S/D 430 that is a source node of the mapping cell 402b and a drain node of the next mapping cell 402c. This configuration continues down to the mapping cell 402K that includes the source/drain node S/D 432, a gate node GK 434 that is connected to each of the gate nodes G of the transistors M1 and M2 in the mapping cell 402K, a combined source and drain MD layer 436, and a source node S 438.

In some embodiments, the drain node D, the source/drain nodes S/D, and the source node S of the semiconductor structure 410 are situated at the same positions in the semiconductor structure 410 as in a semiconductor structure of a series combination of IO electrical devices, such as electrical device 20 of FIG. 1.

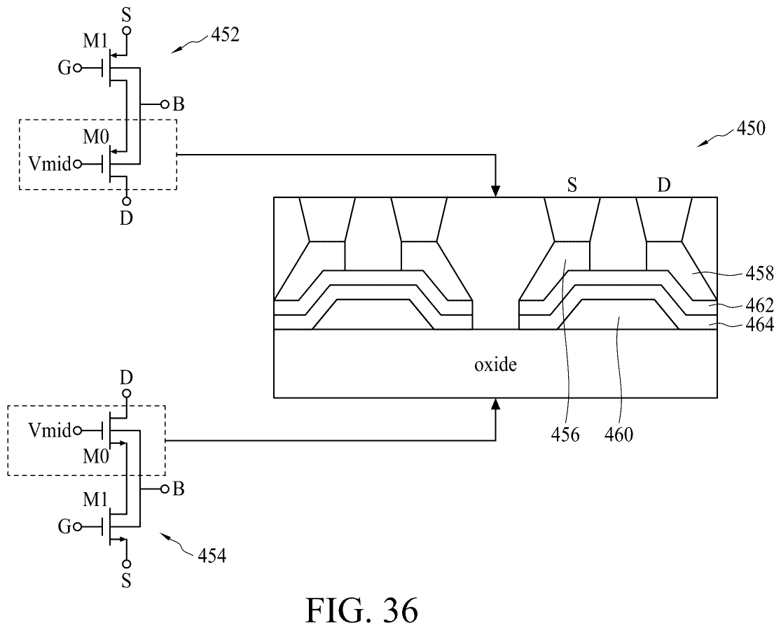

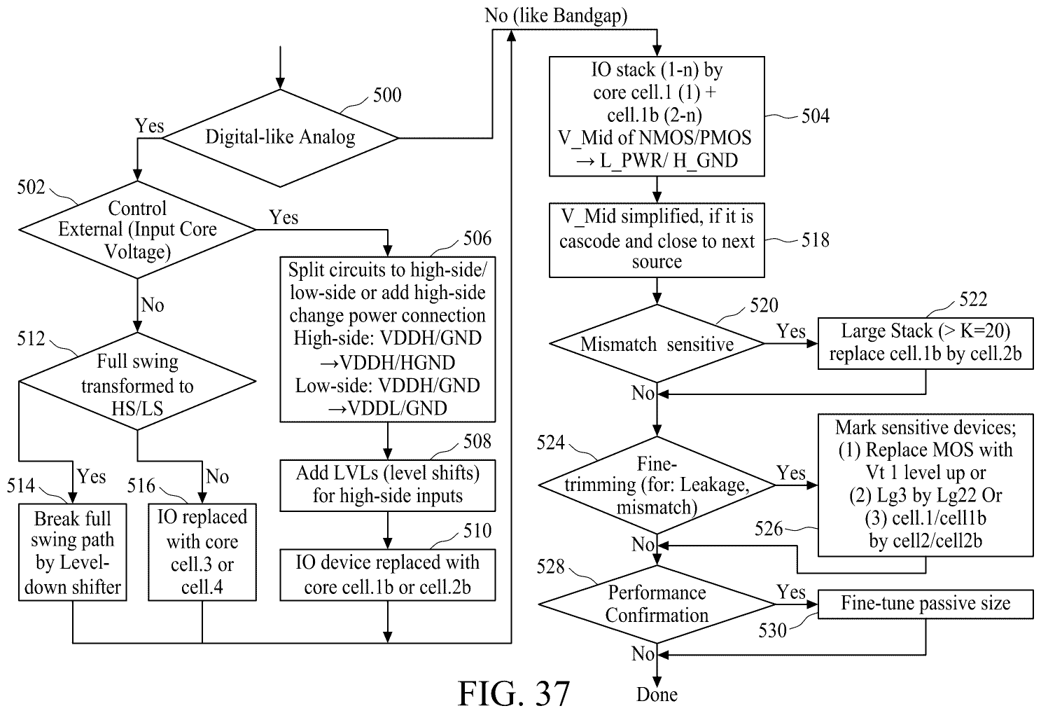

FIG. 36 is a diagram schematically illustrating a cascode transistor M0 450 manufactured by back-end-of-line (BEOL) processes, in accordance with some embodiments. The cascode transistor M0 450 is part of a PMOS mapping cell 452 or part of an NMOS mapping cell 454. The cascode transistor M0 450 includes a drain node D, a gate node Vmid, a body node B, and a source node connected in series to a drain of the transistor M1 that includes a gate node G, a source node S, and a body node B. In some embodiments, the PMOS mapping cell 452 is a PMOS version of the mapping cell 22 of FIG. 2. In some embodiments, the NMOS mapping cell 454 is like the mapping cell 22 of FIG. 2. In other embodiments, the cascode transistor M0 450 is manufactured by front-end-of-line (FEOL) processes.

As a BEOL transistor, the cascode transistor 450 includes a source 456, a drain 458, a gate 460, a channel 462, and a high-k dielectric 464. In some embodiments, each of the source 456, the drain 458, and the gate 460 includes titanium nitride (TiN). In some embodiments, the channel includes indium gallium zinc oxide (IGZO) and, in some embodiments, the high-k dielectric includes hafnium oxide (HfO2).

As a BEOL transistor, the cascode transistor M0 450 can be situated above transistor M1 to reduce the integrated circuit area. As a FEOL transistor, the cascode transistor 450 is situated on the same plane as the transistor M1.

FIG. 37 is a diagram schematically illustrating a method of transforming IO domain circuits into core domain mapping cells, in accordance with some embodiments.

At step 500, the method includes determining if the IO domain circuit is a digital-like analog circuit, such as a mixed signal circuit, or an analog based design, such as a band-gap design. If the IO domain circuit is a digital-like analog circuit, the method continues at step 502, and if the IO domain circuit is an analog based design the method continues at step 504.

At step 502, the method includes determining if control of the circuit is external, such as with an input core domain voltage. If it is, at step 506 the method continues with splitting the circuit into a high voltage side and a low voltage side or adding a high voltage side to the circuit. Then, at step 508, the method includes adding level shifters for high-side inputs to the circuit and, at step 510, replacing the IO devices with reduced core domain mapping cells, such as mapping cell. 1b and mapping cell.2b. The method continues at step 504.

If control of the circuit is determined to be not external at step 502, the method continues at step 512 by determining whether the full swing is transformed to the high voltage side or the low voltage side. If it is, the method continues at step 514 with breaking the full swing path by level-down shifters and then continues at step 504. If it is not, the method continues at step 516 with replacing the circuit with core domain mapping cells, such as mapping cell.3 and mapping cell.4 and then continues at step 504.

At step 504, the method continues with replacing an IO stack with core domain mapping cells, such as mapping cell. 1 and/or mapping cell.1b, and providing the gate node Vmid voltage for the NMOS/PMOS circuits, such as low power (L_PWR)/high power (H_PWR). At step 518, the method continues with simplifying the gate node Vmid voltage if it is a cascode transistor and close to the next voltage source.

The method continues at step 520 with determining whether the circuit is mismatch sensitive. If it is, then, at step 522 the method continues with replacing mapping cells in a large stack with the reduced mapping cells, such as mapping cell. 1b and mapping cell.2b. The method continues at step 524. If it is not, the method continues at step 524.

At step 524, the method includes determining whether fine-trimming for items such as leakage and mismatch needs to be performed. If it does, the method continues at step 526 with marking sensitive devices and performing steps such as replacing MOS transistors with threshold voltages that are one level higher, increasing the channel length such as from length 3 to length 22 or replacing mapping cell. 1/cell.1b with mapping cell.2/cell.2b and the method continues at step 528. If it does not, the method continues at step 528.

At step 528, the method includes determining performance confirmation. If it does, at step 530, the method includes fine-tuning passive sizes and then the method is done. If it does not the method is done.

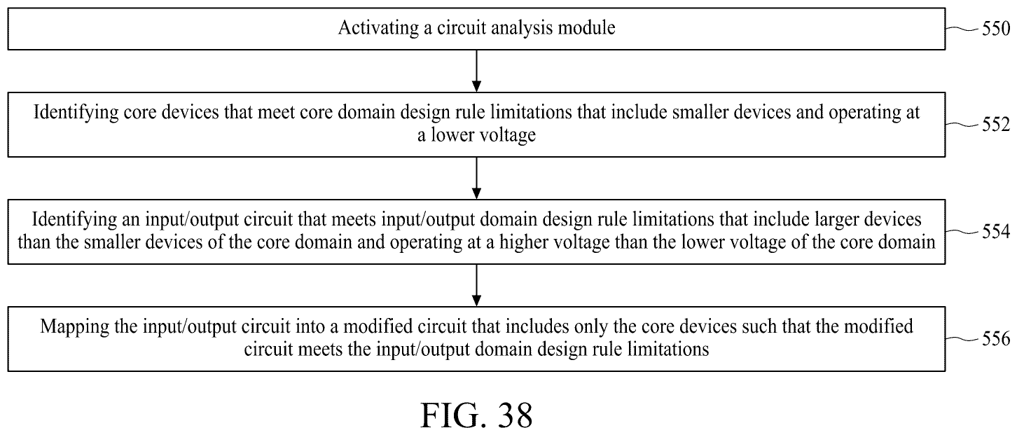

FIG. 38 is a diagram schematically illustrating a mapping method, in accordance with some embodiments. At 550, the method includes activating a circuit analysis module and, at 552, the method includes identifying core devices that meet core domain design rule limitations that include smaller devices and operating at a lower voltage. At 554, the method includes identifying an input/output circuit that meets input/output domain design rule limitations that include larger devices than the smaller devices of the core domain and operating at a higher voltage than the lower voltage of the core domain. At 556, the method includes mapping the input/output circuit into a modified circuit that includes only the core devices such that the modified circuit meets the input/output domain design rule limitations.

In some embodiments, the method includes wherein mapping the input/output circuit into the modified circuit includes mapping each input/output device into two or more core devices that meet the core domain design rule limitations, such that the modified circuit operates in the input/output domain at the higher voltage. In some embodiments, the method includes wherein mapping each input/output device into two or more core devices includes mapping each input/output device into a first core device that operates as a cascode protection device and a second core device that is connected in series to the first core device. In some embodiments, the method includes wherein mapping each input/output device into two or more core devices includes mapping each input/output device into a first core device that operates as a cascode protection device, a second core device that is connected in series to the first core device, and a third core device that is connected to each gate of the first core device and the second core device.

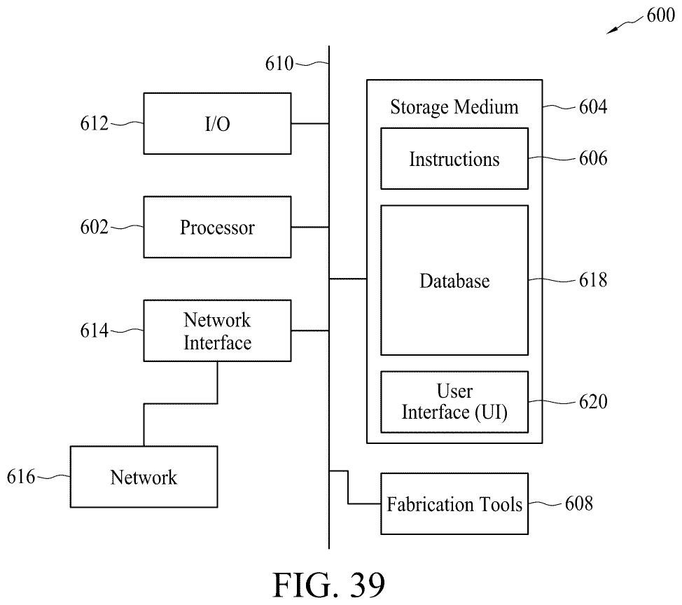

FIG. 39 is a block diagram schematically illustrating an example of a computer system 600 configured to provide the semiconductor devices and methods of the current disclosure, in accordance with some embodiments. Some or all the design, mapping, and manufacture of the semiconductor devices, also referred to as semiconductor circuits, can be performed by or with the computer system 600. In some embodiments, the computer system 600 includes an electronic design automation (EDA) system. In some embodiments, the computer system 600 includes a circuit analysis module for performing method steps of the current disclosure. In some embodiments, the semiconductor devices are ICs.

In some embodiments, the system 600 is a general-purpose computing device including a processor 602 and a non-transitory, computer-readable storage medium 604. The computer-readable storage medium 604 may be encoded with, e.g., store, computer program code such as executable instructions 606. Execution of the instructions 606 by the processor 602 provides (at least in part) a design tool that implements a portion or all the functions of the system 600, such as pre-layout simulations, post-layout simulations, routing, rerouting, and final layout for manufacturing. Further, fabrication tools 608 are included to further layout and physically implement the design and manufacture of the semiconductor devices. In some embodiments, execution of the instructions 606 by the processor 602 provides (at least in part) a design tool that implements a portion or all the functions of the system 600 including transformation mapping from IO domain circuits to core device mapping cells, as described herein. In some embodiments, the system 600 includes a commercial router. In some embodiments, the system 600 includes an automatic place and route (APR) system.

The processor 602 is electrically coupled to the computer-readable storage medium 604 by a bus 610 and to an I/O interface 612 by the bus 610. A network interface 614 is also electrically connected to the processor 602 by the bus 610. The network interface 614 is connected to a network 616, so that the processor 602 and the computer-readable storage medium 604 can connect to external elements using the network 616. The processor 602 is configured to execute the computer program code or instructions 606 encoded in the computer-readable storage medium 604 to cause the system 600 to perform a portion or all the functions of the system 600, such as providing the semiconductor devices and methods of the current disclosure and other functions of the system 600. In some embodiments, the processor 602 is a central processing unit (CPU), a multi-processor, a distributed processing system, an application specific integrated circuit (ASIC), and/or a suitable processing unit.

In some embodiments, the computer-readable storage medium 604 is an electronic, magnetic, optical, electromagnetic, infrared, and/or semiconductor system or apparatus or device. For example, the computer-readable storage medium 604 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 604 can include a compact disk read only memory (CD-ROM), a compact disk read/write memory (CD-R/W), and/or a digital video disc (DVD).

In some embodiments, the computer-readable storage medium 604 stores computer program code or instructions 606 configured to cause the system 600 to perform a portion or all the functions of the system 600. In some embodiments, the computer-readable storage medium 604 also stores information which facilitates performing a portion or all the functions of the system 600. In some embodiments, the computer-readable storage medium 604 stores a database 618 that includes one or more of component libraries, digital circuit cell libraries, and databases.

The system 600 includes the I/O interface 612, which is coupled to external circuitry. In some embodiments, the I/O interface 612 includes a keyboard, keypad, mouse, trackball, trackpad, touchscreen, and/or cursor direction keys for communicating information and commands to the processor 602.

The network interface 614 is coupled to the processor 602 and allows the system 600 to communicate with the network 616, to which one or more other computer systems are connected. The network interface 614 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 600 can be performed in two or more systems that are like system 600.

The system 600 is configured to receive information through the I/O interface 612. The information received through the I/O interface 612 includes one or more of instructions, data, design rules, libraries of components and cells, and/or other parameters for processing by the processor 602. The information is transferred to the processor 602 by the bus 610. Also, the system 600 is configured to receive information related to a user interface (UI) through the I/O interface 612. This UI information can be stored in the computer-readable storage medium 604 as a UI 620.

In some embodiments, a portion or all the functions of the system 600 are implemented via a standalone software application for execution by a processor. In some embodiments, a portion or all the functions of the system 600 are implemented in a software application that is a part of an additional software application. In some embodiments, a portion or all the functions of the system 600 are implemented as a plug-in to a software application. In some embodiments, at least one of the functions of the system 600 is implemented as a software application that is a portion of an EDA tool. In some embodiments, a portion or all the functions of the system 600 are implemented as a software application that is used by the system 600. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 600 include fabrication tools 608 for implementing the manufacturing processes of the system 600. For example, based on the final layout, photolithographic masks may be generated, which are used to fabricate the semiconductor device by the fabrication tools 608.

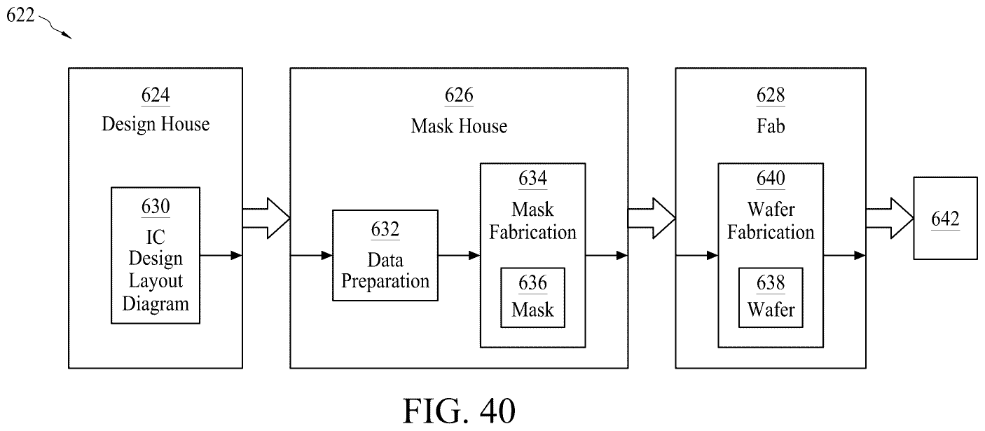

Further aspects of device fabrication are disclosed in conjunction with FIG. 40, which is a block diagram of a semiconductor device manufacturing system 622 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 622.

In FIG. 40, the semiconductor device manufacturing system 622 includes entities, such as a design house 624, a mask house 626, and a semiconductor device manufacturer/fabricator (“Fab”) 628, that interact with one another in the design, development, and manufacturing cycles and/or services related to manufacturing a semiconductor device, such as the semiconductor devices described herein. The entities in the system 622 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 624, the mask house 626, and the semiconductor device fab 628 are owned by a single larger company. In some embodiments, two or more of the design house 624, the mask house 626, and the semiconductor device fab 628 coexist in a common facility and use common resources.

The design house (or design team) 624 generates a semiconductor device design layout diagram 630. The semiconductor device design layout diagram 630 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 630 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 624 implements a design procedure to form a semiconductor device design layout diagram 630. The semiconductor device design layout diagram 630 is presented in one or more data files having information of the geometrical patterns. For example, semiconductor device design layout diagram 630 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 626 includes data preparation 632 and mask fabrication 634. The mask house 626 uses the semiconductor device design layout diagram 630 to manufacture one or more masks 636 to be used for fabricating the various layers of the semiconductor device or semiconductor structure. The mask house 626 performs mask data preparation 632, where the semiconductor device design layout diagram 630 is translated into a representative data file (RDF). The mask data preparation 632 provides the RDF to the mask fabrication 634. The mask fabrication 634 includes a mask writer that converts the RDF to an image on a substrate, such as a mask (reticle) 636 or a semiconductor wafer 638. The design layout diagram 630 is manipulated by the mask data preparation 632 to comply with characteristics of the mask writer and/or criteria of the semiconductor device fab 628. In FIG. 40, the mask data preparation 632 and the mask fabrication 634 are illustrated as separate elements. In some embodiments, the mask data preparation 632 and the mask fabrication 634 can be collectively referred to as mask data preparation.

In some embodiments, the mask data preparation 632 includes an optical proximity correction (OPC) which uses lithography enhancement techniques to compensate for image errors, such as those that can arise from diffraction, interference, other process effects and the like. The OPC adjusts the semiconductor device design layout diagram 630. In some embodiments, the mask data preparation 632 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 632 includes a mask rule checker (MRC) that checks the semiconductor device design layout diagram 630 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 630 to compensate for limitations during the mask fabrication 634, which may undo part of the modifications performed by OPC to meet mask creation rules.

In some embodiments, the mask data preparation 632 includes lithography process checking (LPC) that simulates processing that will be implemented by the semiconductor device fab 628. LPC simulates this processing based on the semiconductor device design layout diagram 630 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine the semiconductor device design layout diagram 630.

The above description of mask data preparation 632 has been simplified for the purposes of clarity. In some embodiments, data preparation 632 includes additional features such as a logic operation (LOP) to modify the semiconductor device design layout diagram 630 according to manufacturing rules. Additionally, the processes applied to the semiconductor device design layout diagram 630 during data preparation 632 may be executed in a variety of different orders.

After the mask data preparation 632 and during the mask fabrication 634, a mask 636 or a group of masks 636 are fabricated based on the modified semiconductor device design layout diagram 630. In some embodiments, the mask fabrication 634 includes performing one or more lithographic exposures based on the semiconductor device design layout diagram 630. In some embodiments, an electron-beam (e-beam) or a mechanism of multiple e-beams is used to form a pattern on a mask (photomask or reticle) 636 based on the modified semiconductor device design layout diagram 630. The mask 636 can be formed in various technologies. In some embodiments, the mask 636 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 636 includes a transparent substrate (e.g., fused quartz) and an opaque material (e.g., chromium) coated in the opaque regions of the binary mask. In another example, the mask 636 is formed using a phase shift technology. In a phase shift mask (PSM) version of the mask 636, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 634 is used in a variety of processes. For example, such a mask(s) is used in an ion implantation process to form various doped regions in the semiconductor wafer 638, in an etching process to form various etching regions in the semiconductor wafer 638, and/or in other suitable processes.

The semiconductor device fab 628 includes wafer fabrication 640. The semiconductor device fab 628 is a semiconductor device fabrication business that includes one or more manufacturing facilities for the fabrication of a variety of different semiconductor device products. In some embodiments, the semiconductor device fab 628 is a semiconductor foundry. For example, there may be a manufacturing facility for the front end of line (FEOL) fabrication of a plurality of semiconductor device products, while a second manufacturing facility may provide the back end of line (BEOL) fabrication for the interconnection and packaging of the semiconductor device products, and a third manufacturing facility may provide other services for the foundry business.

The semiconductor device fab 628 uses the mask(s) 636 fabricated by the mask house 626 to fabricate the semiconductor structures or semiconductor devices 642 of the current disclosure. Thus, the semiconductor device fab 628 at least indirectly uses the semiconductor device design layout diagram 630 to fabricate the semiconductor structures or semiconductor devices 642 of the current disclosure. Also, the semiconductor wafer 638 includes a silicon substrate or other proper substrate having material layers formed thereon, and the semiconductor wafer 638 further includes one or more of various doped regions, dielectric features, multilevel interconnects, and the like (formed at subsequent manufacturing steps). In some embodiments, the semiconductor wafer 638 is fabricated by the semiconductor device fab 628 using the mask(s) 636 to form the semiconductor structures or semiconductor devices 642 of the current disclosure. In some embodiments, the semiconductor device fabrication includes performing one or more lithographic exposures based at least indirectly on the semiconductor device design layout diagram 630.

Disclosed embodiments thus provide mapping cell structures and methods for replacing the IO electrical devices that meet design rule limitations of an IO domain with two or more core electrical devices that meet design rule limitations of a core domain. The result is a core device only circuit and design flow that maintains comparable performance to the replaced IO electrical devices that meet the design rule limitations of the IO domain including the higher voltages of the IO domain. The mapping cells can be NMOS mapping cells or PMOS mapping cells.

Advantages of the disclosed embodiments include mapping cells that work in the design and layout of an IC to achieve quick and easy replacement, mapping cells composed of one or more cascode protection devices that allow connections to higher voltages, and mapping cells that have comparable PPA to IO electrical devices. Also, this design flow provides for analog-based design like band-gap circuits and for digital-like analog design as in mixed-signal circuits.

In accordance with some embodiments, an integrated circuit includes a core domain having at least one core domain design rule limitation of a smaller device and a lower operating voltage, an input/output domain having at least one input/output domain design rule limitation of a larger device than the smaller device of the core domain and a higher operating voltage than the lower operating voltage of the core domain, and a mapping cell that includes two or more electrical devices that each meet the at least one core domain design rule limitation. The mapping cell is configured to be an input/output device and operate in the input/output domain at the higher operating voltage of the input/output domain.

In accordance with further embodiments, a semiconductor circuit includes a core domain having at least one core domain design rule limitation of a smaller device and a lower operating voltage, an input/output domain having at least one input/output domain design rule limitation of a larger device than the smaller device of the core domain and a higher operating voltage than the lower operating voltage of the core domain, a set of core devices that meet the at least one core domain design rule limitation, a core circuit that includes first core devices of the set of core devices, and an input/output circuit that includes second core devices of the set of core devices, wherein the input/output circuit operates at the higher operating voltage.

In accordance with still further disclosed aspects, a mapping method includes activating a circuit analysis module, identifying core devices that meet at least one core domain design rule limitation of a smaller device and a lower operating voltage, identifying an input/output circuit that meets at least one input/output domain design rule limitation of a larger device than the smaller device of the core domain and a higher operating voltage than the lower operating voltage of the core domain, and mapping the input/output circuit into a modified circuit that includes only the core devices such that the modified circuit meets the at least one input/output domain design rule limitation.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a core domain having at least one core domain design rule limitation of a smaller device and a lower operating voltage;
an input/output domain having at least one input/output domain design rule limitation of a larger device than the smaller device of the core domain and a higher operating voltage than the lower operating voltage of the core domain; and
a mapping cell that includes two or more electrical devices that each meet the at least one core domain design rule limitation,
wherein the mapping cell is configured to be an input/output device and operate in the input/output domain at the higher operating voltage of the input/output domain.

2. The integrated circuit of claim 1, wherein the mapping cell includes a cascode protection device that meets the at least one core domain design rule limitation connected in series with a core device that meets the at least one core domain design rule limitation.

3. The integrated circuit of claim 2, wherein the mapping cell includes a first input device connected to gates of the cascode protection device and the core device.

4. The integrated circuit of claim 3, wherein the mapping cell includes a second input device connected to gates of the cascode protection device, the core device, and the first input device.

5. The integrated circuit of claim 1, wherein the mapping cell includes a cascode protection device that meets the at least one core domain design rule limitation connected in series with two or more core devices that meet the at least one core domain design rule limitation.

6. The integrated circuit of claim 1, wherein the mapping cell includes two or more cascode protection devices that meet the at least one core domain design rule limitation connected in series with a core device that meets the at least one core domain design rule limitation.

7. The integrated circuit of claim 1, wherein the mapping cell is configured to operate in an analog application.

8. The integrated circuit of claim 1, wherein the mapping cell is configured to operate in one or more of a mixed signal application and a rail-to-rail application.

9. The integrated circuit of claim 1, wherein each of the two or more electrical devices is an n-channel metal-oxide semiconductor field-effect transistor.

10. The integrated circuit of claim 1, wherein each of the two or more electrical devices is a p-channel metal-oxide semiconductor field-effect transistor.

11. A semiconductor circuit comprising:
a core domain having at least one core domain design rule limitation of a smaller device and a lower operating voltage;
an input/output domain having at least one input/output domain design rule limitation of a larger device than the smaller device of the core domain and a higher operating voltage than the lower operating voltage of the core domain;
a set of core devices that meet the at least one core domain design rule limitation;
a core circuit that includes first core devices of the set of core devices; and
an input/output circuit that includes second core devices of the set of core devices, wherein the input/output circuit operates at the higher operating voltage.

12. The semiconductor circuit of claim 11, wherein the set of core devices includes front-end-of-line devices.

13. The semiconductor circuit of claim 11, wherein the set of core devices includes back-end-of-line devices.

14. The semiconductor circuit of claim 11, wherein the second core devices include one core device connected in series to another core device.

15. The semiconductor circuit of claim 14, wherein the one core device and the other core device are located on a same plane in the semiconductor circuit.

16. The semiconductor circuit of claim 14, wherein the one core device and the other core device are located on different planes in the semiconductor circuit.

17. A mapping method comprising:
activating a circuit analysis module;
identifying core devices that meet at least one core domain design rule limitation of a smaller device and a lower operating voltage;
identifying an input/output circuit that meets at least one input/output domain design rule limitation of a larger device than the smaller device of the core domain and a higher operating voltage than the lower operating voltage of the core domain; and
mapping the input/output circuit into a modified circuit that includes only the core devices such that the modified circuit meets the at least one input/output domain design rule limitation.

18. The method of claim 17, wherein mapping the input/output circuit into the modified circuit includes mapping each input/output device into two or more core devices that meet the at least one core domain design rule limitation, wherein the modified circuit operates in the input/output domain at the higher operating voltage.

19. The method of claim 18, wherein mapping each input/output device into two or more core devices includes mapping each input/output device into a first core device that operates as a cascode protection device and a second core device that is connected in series to the first core device.

20. The method of claim 18, wherein mapping each input/output device into two or more core devices includes mapping each input/output device into a first core device that operates as a cascode protection device, a second core device that is connected in series to the first core device, and a third core device that is connected to each gate of the first core device and the second core device.
